(19) United States
(12) Patent Application Publication
(10) Pub. No.: US 2011/0076448 A1
(43) Pub. Date: Mar. 31, 2011

(54) Methods for Patterning Substrates Using Heterogeneous Stamps and Stencils and Methods of Making the Stamps and Stencils

(75) Inventors: Sandip AGARWAL, Somerville, MA (US); Graciela Beatriz BLANCHET, Boston, MA (US); Brian T. MAYERS, Arlington, MA (US); Joseph M. MCLELLAN, Quincy, MA (US); Patrick REUST, Allston, MA (US); Eric STERN, Cambridge, MA (US); Jennifer GILLIES, Cambridge, MA (US); Ralf KÜGLER, Cambridge, MA (US)

(73) Assignees: Nano Terra Inc., Cambridge, MA (US); Merck Patent GmbH, Darmstadt (DE)

(21) Appl. No.: 12/859,953

(22) Filed: Aug. 20, 2010

Related U.S. Application Data
(60) Provisional application No. 61/235,866, filed on Aug. 21, 2009.

(51) Int. Cl. B41N 1/24; G03F 7/20; B05D 1/32; B32B 3/24

(52) U.S. Cl. 428/138; 430/325; 427/282

(57) ABSTRACT

The present invention is directed to heterogeneous stamp and stencil compositions, methods for patterning substrates using contact printing processes employing the heterogeneous stamps and stencils, and products formed by the contact printing processes.

### CROSS-REFERENCE TO RELATED APPLICATIONS

This application claims the benefit of the filing date of U.S. Provisional Appl. No. 61/235,866, filed Aug. 21, 2009, which is incorporated herein by reference in its entirety.

### BACKGROUND OF THE INVENTION

1. Field of the Invention

The present invention is directed to methods for patterning substrates using heterogeneous stamps and stencils, methods to prepare the heterogeneous stamps and stencils, and products formed by the patterning processes.

2. Background

Methods of patterning surfaces are well known and include photolithography techniques, as well as the more recently developed soft-contact printing techniques such as “micro-contact printing” (see, e.g., U.S. Pat. No. 5,512,131).

Traditional photolithography methods, while versatile in the architectures and compositions of surface features to be formed, are also costly and require specialized equipment. Moreover, photolithography techniques have difficulty patterning very large and/or non-rigid surfaces such as, for example, textiles, paper, plastics, and the like.

Soft-lithographic techniques have demonstrated the ability to produce surface features having lateral dimension as small as 40 nm or less in a cost-effective, reproducible manner. However, the versatility of soft lithography can be somewhat limited to the type of substrate, the type of pattern, and the reusability of the stamping and/or stenciling tool.

### BRIEF SUMMARY OF THE INVENTION

What is needed are contact printing methods that can produce patterns having lateral dimensions of about 100 μm or less on a wide variety of substrates, using a wide range of compositions for the patterning, and which have a longer usable lifetime.

The present invention is directed to patterning surfaces using contact-printing techniques that employ a “reactive composition” (e.g., an “ink”, “paste”, etc.). Surface features formed by the method of the present invention have lateral dimensions less than 100 μm, and permit all varieties of surfaces to be patterned in a cost-effective, efficient, and reproducible manner.

The present invention is directed to a method for forming a feature on a substrate, the method comprising:
(a) providing a stencil having a front surface and a back surface,
   wherein the front surface of the stencil includes an elastomeric material that defines a pattern thereon, the pattern comprising a plurality of openings having at least one lateral dimension of about 100 μm or less,
   wherein the back surface of the stencil includes a porous membrane that is affixed to at least a portion of the elastomeric material, and
   wherein the front surface of the stencil has a flatness of about 20% or less of the stencil thickness;
(b) conformally contacting the front surface of the stencil with a substrate; and
(c) applying a reactive composition to the back surface of the stencil, wherein the reactive composition permeates the porous membrane and reacts to produce a patterned substrate having a feature thereon, wherein the feature has a lateral dimension corresponding to the plurality of openings in the front surface of the stencil.

The present invention is also directed to a method for forming a feature on a substrate, the method comprising:
(a) providing a stencil having a front surface and a back surface,
   wherein the front surface of the stencil includes an elastomeric material that defines a pattern thereon, the pattern comprising a plurality of openings having a minimum lateral dimension of about 100 μm or less,
   wherein the back surface of the stencil includes a porous membrane that is affixed to at least a portion of the elastomeric material,
(b) conformally contacting the front surface of the stencil with a substrate;
(c) applying a reactive composition to the back surface of the stencil, wherein the reactive composition permeates the porous membrane and contacts the substrate;
(d) removing the stencil from the substrate; and
(e) reacting the reactive composition with the substrate to produce a patterned substrate having a feature thereon, wherein the feature has a lateral dimension corresponding to the plurality of openings in the front surface of the stencil.

The present invention is also directed to a method for forming a feature on a substrate, the method comprising:
(a) providing a stencil having a front surface and a back surface,
   wherein the front surface of the stencil includes a photoimaged elastomeric material that defines a pattern thereon, the pattern comprising a plurality of openings having a minimum lateral dimension of about 1 μm to about 50 μm,
   wherein the back surface of the stencil includes a rigid porous membrane affixed to at least a portion of the elastomeric material, the rigid porous membrane having at least one surface with a flatness of about 20% or less of the stencil thickness and comprises a material selected from: a porous glass membrane, a porous ceramic membrane, and a porous polycarbonate membrane;
(b) conformally contacting the front surface of the stencil with a substrate;
(c) applying a reactive composition to the back surface of the stencil, wherein the reactive composition includes an etchant and has a viscosity of about 10 cP to about 100 cP, and wherein the reactive composition permeates the porous membrane and reacts to produce a patterned substrate having a feature thereon, wherein the feature has a lateral dimension corresponding to the plurality of openings in the front surface of the stencil.

In some embodiments, a method further comprises removing the stencil from the patterned substrate before the reactive composition has completed reacting.

In some embodiments, a method further comprises cleaning the patterned substrate.

In some embodiments, a method further comprises before the conformally contacting, pre-treating at least one of: the front surface of the stencil, the substrate, the porous membrane, or a combination thereof.

In some embodiments, applying comprises applying a reactive composition with: fluid pressure, mechanical pressure, gravity, or a combination thereof.

In some embodiments, a reactive composition comprises an etchant. In some embodiments, a reactive composition comprises an etchant and has a viscosity of about 100 cP to about 10,000 cP.

In some embodiments, a reactive composition comprises a metal nanoparticle. In some embodiments, a reactive composition comprises a metal nanoparticle and has a viscosity of about 10 cP to about 10,000 cP.

In some embodiments, a method further comprises initiating a reaction of the reactive composition, wherein the initiating comprises applying thermal energy, electromagnetic radiation, acoustic waves, an oxidizing or reducing plasma, an electron beam, a stoichiometric chemical reagent, a catalytic chemical reagent, an oxidizing or reducing reactive gas, an acid, a base, an increase or decrease in pressure, an alternating or direct electrical current, agitation, sonication, friction, or a combination thereof to the reactive composition, the substrate, or a combination thereof.

In some embodiments, the conformally contacting is achieved by applying pressure of about 10 kPa or less to the stencil or the substrate.

The present invention is also directed to a method for preparing a stencil, the method comprising:
(a) coating a surface with a photoimageable elastomeric precursor to provide a coating layer comprising a photoimageable elastomeric precursor;
(b) patterning the photoimageable elastomeric precursor to provide an elastomeric layer that includes a plurality of openings therein, the openings having at least one lateral dimension of about 100 μm or less;
(c) affixing a porous membrane to the elastomeric layer;
(d) separating the elastomeric layer from the surface, thereby providing the stencil, wherein the front surface of the stencil has a flatness of about 20% or less of the stencil thickness.

The present invention is also directed to a method for preparing a stencil, the method comprising:
(a) coating a porous membrane with a photoimageable elastomeric precursor to provide a coating layer comprising a photoimageable elastomeric precursor; and
(b) patterning the photoimageable elastomeric precursor coating layer to provide the stencil comprising a patterned elastomeric layer on the porous membrane, wherein the patterned elastomeric layer includes a plurality of openings therein, the openings having at least one lateral dimension of about 100 μm or less, and wherein the front surface of the stencil has a flatness of about 20% or less of the stencil thickness.

In some embodiments, a photoimageable elastomeric precursor having a thickness of about 1 μm to about 30 μm.

In some embodiments, the patterning comprises:
(i) positioning a photomask proximate to the coating layer comprising a photoimageable elastomeric precursor;
(ii) exposing the photoimageable precursor through the photomask with UV radiation for about 0.1 seconds to about 100 seconds to provide a photoimaged coating layer;
(iii) developing the photoimaged coating layer to remove regions of the photoimaged coating layer and provide a patterned elastomeric layer; and
(iv) drying the surface of the patterned elastomeric layer.

In some embodiments, a photoimageable elastomeric precursor comprises: a photocurable monomer, an elastomeric binder, and a photoinitiator.

Photocurable monomers suitable for use with the present invention include, but are not limited to, a linear acrylate, a branched acrylate, a methacrylate, and combinations thereof.

In some embodiments, an elastomeric binder has an accessible vinyl side-chain. Elastomeric binders suitable for use with the present invention include but are not limited to, a styrene butadiene rubber, a styrene isoprene rubber, a polyurethane, and a polysiloxane.

Photoinitiators suitable for use with the present invention include, but are not limited to, Irgacure 907, Esacure TZT, Esacure SM308, and combinations thereof.

Coating methods suitable for use with the present invention include, but are not limited to, spin-coating, dip-coating, spray-coating, and slit-coating. In some embodiments, a photoimageable elastomeric precursor includes a solvent. Solvents suitable for use with the photoimageable elastomeric precursor include, but are not limited to, toluene, xylene, propylene glycol methyl ether acetate, and combinations thereof.

In some embodiments, a photoimageable elastomeric precursor further comprises an additive such as, but not limited to, a wetting agent, a stabilizer, an anti-oxidant, a photocuring accelerator, and combinations thereof.

Stabilizers suitable for use with the present invention include, but are not limited to, 2,6-di-tert-butyl-4-methylphenol, 1,4,4-trimethyl-2,3-diazobicyclo(3.2.2)-non-2-ene-2,3-dioxide, and combinations thereof.

In some embodiments, a method further comprises adhering at least a portion of the porous membrane to a rigid member to provide a stencil in which the front surface has a flatness of about 20% or less of the stencil thickness.

In some embodiments, a porous membrane has a thickness of about 50 μm to about 1,000 μm. In some embodiments, a porous membrane having an average pore size of about 100 nm to about 2 μm.

In some embodiments, a porous membrane has a thickness of about 50 μm to about 1,000 μm and an average pore size of about 100 nm to about 2 μm, which in some embodiments is used in conjunction with a reactive composition comprising a metal nanoparticle and having a viscosity of about 10 cP to about 10,000 cP.

In some embodiments, an elastomeric material has a thickness not greater than five times the minimum lateral dimension of the plurality of openings.

In some embodiments, an elastomeric material is a photoimaged elastomer selected from: a styrene butadiene rubber, a styrene isoprene rubber, a polyurethane, a polysiloxane, a polyacrylate, a polymethacrylate, and combinations thereof.

In some embodiments, a stencil includes a rigid porous membrane and the front surface of the stencil has a flatness of about 20% or less of the stencil thickness, wherein the rigid porous membrane is selected from: a glass membrane, a ceramic membrane, and a polycarbonate membrane. In some embodiments, a stencil that includes a rigid member has a front surface with a flatness of about 20% or less of the stencil thickness.

In some embodiments, a porous membrane selected from: a nylon membrane, a polyethersulfone membrane, a polypropylene membrane, a poly(tetrafluoroethylene) membrane, a polycarbonate membrane, a cellulose acetate membrane, a sintered plastic membrane, a carbon fiber membrane, a glass fiber membrane, a glass membrane, and a ceramic membrane.

In some embodiments, a stencil has a surface area of about 25 cm² or greater.

The present invention is also directed to a method for forming a feature on a substrate, the method comprising:
(a) providing a stencil having a front surface and a back surface,
   wherein the front surface of the stencil includes a patterned elastomeric material having a thickness of about 1 μm to about 30 μm,
   wherein the back surface of the stencil includes a porous membrane that is affixed to at least a portion of the elastomeric material,
   wherein the front surface of the stencil has a flatness of 20% or less than the stencil thickness, and
   wherein the providing comprises:
      coating the porous membrane with a photoimageable elastomeric precursor to provide a coating layer comprising a photoimageable elastomeric precursor;
      positioning a photomask proximate to the coating layer comprising a photoimageable elastomeric precursor;
      exposing the photoimageable precursor through the photomask with UV radiation for about 0.1 seconds to about 100 seconds to provide a photoimaged coating layer;
      developing the photoimaged coating layer to remove regions of the photoimaged coating layer and provide a patterned elastomeric layer; and
      drying the surface of the patterned elastomeric layer to provide the stencil comprising a patterned elastomeric layer on the porous membrane, wherein the patterned elastomeric layer includes a plurality of openings therein, the openings having at least one lateral dimension of about 100 μm or less;
(b) conformally contacting the front surface of the stencil with a substrate; and
(c) applying a reactive composition to the back surface of the stencil, wherein the reactive composition permeates the porous membrane and reacts to produce a patterned substrate having a feature thereon, wherein the feature has a lateral dimension corresponding to the plurality of openings in the front surface of the stencil.

The present invention is also directed to a method for forming a feature on a substrate, the method comprising:
(a) providing a stencil having a front surface and a back surface,
   wherein the front surface of the stencil includes a patterned elastomeric material having a thickness of about 1 μm to about 30 μm,
   wherein the back surface of the stencil includes a porous membrane that is affixed to at least a portion of the elastomeric material,
   wherein the front surface of the stencil has a flatness of 20% or less than the stencil thickness, and
   wherein the providing comprises:
      coating the porous membrane with a photoimageable elastomeric precursor to provide a coating layer comprising a photoimageable elastomeric precursor;
      positioning a photomask proximate to the coating layer comprising a photoimageable elastomeric precursor;
      exposing the photoimageable precursor through the photomask with UV radiation for about 0.1 seconds to about 100 seconds to provide a photoimaged coating layer;
      developing the photoimaged coating layer to remove regions of the photoimaged coating layer and provide a patterned elastomeric layer; and
      drying the surface of the patterned elastomeric layer to provide the stencil comprising a patterned elastomeric layer on the porous membrane, wherein the patterned elastomeric layer includes a plurality of openings therein, the openings having at least one lateral dimension of about 100 μm or less;
(b) conformally contacting the front surface of the stencil with a substrate; and
(c) applying a reactive composition comprising a nanoparticle to the back surface of the stencil, wherein the reactive composition permeates the porous membrane and produces a patterned substrate having a feature thereon, wherein the feature has a lateral dimension corresponding to the plurality of openings in the front surface of the stencil.

The present invention is also directed to a method for forming a feature on a substrate, the method comprising:
(a) providing a stencil having a front surface and a back surface,
   wherein the front surface of the stencil includes a patterned elastomeric material having a thickness of about 1 μm to about 30 μm,
   wherein the back surface of the stencil includes a porous membrane that is affixed to at least a portion of the elastomeric material,
   wherein the front surface of the stencil has a flatness of 20% or less than the stencil thickness, and
   wherein the providing comprises:
      coating the porous membrane with a photoimageable elastomeric precursor to provide a coating layer comprising a photoimageable elastomeric precursor;
      positioning a photomask proximate to the coating layer comprising a photoimageable elastomeric precursor;
      exposing the photoimageable precursor through the photomask with UV radiation for about 0.1 seconds to about 100 seconds to provide a photoimaged coating layer;
      developing the photoimaged coating layer to remove regions of the photoimaged coating layer and provide a patterned elastomeric layer; and
      drying the surface of the patterned elastomeric layer to provide the stencil comprising a patterned elastomeric layer on the porous membrane, wherein the patterned elastomeric layer includes a plurality of openings therein, the openings having at least one lateral dimension of about 100 μm or less;
(b) conformally contacting the front surface of the stencil with a substrate; and
(c) applying a reactive composition comprising a nanoparticle to the back surface of the stencil, wherein the reactive composition permeates the porous membrane and contacts the substrate to form a patterned substrate, wherein the pattern corresponds to the plurality of openings in the front surface of the stencil;
(d) removing the stencil from the substrate; and
(e) sintering the patterned substrate at a temperature of about 60° C. to about 600° C.

The present invention is also directed to products prepared by the above methods. In some embodiments, a product is a stencil having a surface area of about 25 cm² or greater.

Further embodiments, features, and advantages of the present inventions, as well as the structure and operation of the various embodiments of the present invention, are described in detail below with reference to the accompanying drawings.

### BRIEF DESCRIPTION OF THE DRAWINGS

The accompanying drawings, which are incorporated herein and form a part of the specification, illustrate one or more embodiments of the present invention and, together with the description, further serve to explain the principles of the invention and to enable a person skilled in the pertinent art to make and use the invention.

FIG. 1A-1E provide cross-sectional schematic representations of heterogeneous stencils of the present invention.

FIGS. 2A-2B and 2C-2D provide three-dimensional schematic representations of embodiments of a heterogeneous stamp of the present invention.

FIGS. 3A-3D, 4A-4E and 5A-5E provide schematic cross-sectional representations of processes for preparing heterogeneous stamps of the present invention.

FIGS. 6A-6E, 7A-7E, 8A-8E, 9A-9E and 10A-10D provide schematic cross-sectional representations of processes for preparing heterogeneous stencils of the present invention.

FIGS. 11A-11G provide schematic cross-sectional representations of surfaces having surface features thereon that can be prepared by a method of the present invention.

FIG. 12 provides a schematic cross-sectional representation of a curved surface having surface features thereon that can be prepared by a method of the present invention.

FIG. 13 provides a photographic image of a heterogeneous stencil prepared by a process of the present invention.

FIG. 14 provides a transmission mode optical microscopy image of a silicon substrate having a layer of patterned photoresist thereon, which is suitable for use as a portion of a heterogeneous stencil of the present invention

FIGS. 15 and 16 provide scanning electron microscopy images of heterogeneous stencils of the present invention.

FIGS. 17-19 provide transmission mode optical microscopy images of substrates patterned using a heterogeneous stencil of the present invention.

One or more embodiments of the present invention will now be described with reference to the accompanying drawings. In the drawings, like reference numbers can indicate identical or functionally similar elements. Additionally, the left-most digit(s) of a reference number can identify the drawing in which the reference number first appears.

### DETAILED DESCRIPTION OF THE INVENTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment”, “an embodiment”, “an example embodiment”, etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

As used herein, “at least one” refers to one or more.

As used herein, a “plurality” refers to two or more.

References to spatial descriptions (e.g., “above,” “below,” “up,” “down,” “top,” “bottom,” etc.) made herein are for purposes of description and illustration only, and should be interpreted as non-limiting upon the stencils, stamps, methods, and products of the present invention, which can be spatially arranged in any orientation or manner.

### Heterogeneous Stamps and Stencils

The present invention is directed to a heterogeneous stamp composition comprising an elastomeric material having a surface comprising heterogeneous areas having a boundary there between, and a reactive composition deposited on the surface of the stamp; wherein the heterogeneous areas define a pattern in the surface of the elastomeric material, wherein the pattern in the surface of the elastomeric material has a minimum lateral dimension of about 40 nm to about 100 μm, and wherein the reactive composition has a differential affinity for the heterogeneous areas.

The present invention is also directed to a heterogeneous stencil composition comprising a front surface and a back surface, wherein the front surface of the stencil includes an elastomeric material that defines a pattern thereon, the pattern comprising a plurality of openings having at least one lateral dimension of about 100 μm or less, wherein the back surface of the stencil includes a porous membrane that is affixed to at least a portion of the elastomeric material, and wherein the front surface of the stencil has a flatness of about 20% or less of the stencil thickness.

As used herein, a “stamp” refers to a molded three dimensional object having heterogeneous surface areas, and is suitable for conformally contacting a substrate. Stamps for use with the present invention are not particularly limited by geometry, and can be flat, curved, smooth, rough, wavy, and combinations thereof.

Stamps of the present invention can be prepared from elastomeric materials such as, but not limited to, polydimethylsiloxane, polysilsesquioxane, polyisoprene, polybutadiene, polychloroprene, teflon, polycarbonate resins, cross-linked epoxy resins, acryloxy perfluoropolyethers, alkylacryloxy perfluoropolyethers, and combinations thereof. Other materials and methods to prepare elastomeric stamps and stencils of the present invention are disclosed in U.S. Pat. Nos. 5,512,131; 5,900,160; 6,180,239; and 6,776,094; and pending U.S. application Ser. No. 10/766,427, all of which are incorporated herein by reference in their entirety. In some embodiments, the composition of an elastomeric material for use with the present invention is substantially homogeneous. In some embodiments, the composition of an elastomeric material for use with the present invention has a gradient, or a multi-laminate structure.

As used herein, a “stencil” refers to a three dimensional object having: a contact layer that is prepared from a first material that is substantially impermeable to a reactive composition, and includes at least one opening there through defining a pattern in the contact layer; and a backing layer affixed, bonded, or otherwise attached to the contact layer that is substantially permeable to a reactive composition and suitable for maintaining the dimensional stability of the contact layer. In some embodiments, a reactive composition (e.g., an ink, a paste, etc.) is applied to a backside of the stencil and contacted with a substrate. The reactive composition flows through the permeable backing layer to contact the substrate in a pattern according to the pattern of openings in the contact layer. Stencils for use with the present invention are not particularly limited by geometry, and can be flat, curved, smooth, rough, wavy, and combinations thereof.

A stencil has front surface and a back surface, wherein the front surface comprises a contact layer having a surface free energy and three-dimensional shape suitable for conformally contacting a substrate. In some embodiments, a material present on a front surface of a stencil (i.e., the contact layer) has a surface free energy and a three-dimensional shape suitable for conformally contacting a substrate without pressure being applied to a backside of the stencil or a backside of the substrate.

As used herein, “heterogeneous” refers to a composition comprising two or more surfaces, wherein a finite boundary is present between the surfaces such that a reactive composition applied to a first surface and a second surface has a different affinity for the first and second surfaces of the heterogeneous stamp composition. As used herein, an “affinity” refers to an attractive property, a repulsive property, a wetting property, an absorbent property, an adsorbent property, and combinations thereof. In some embodiments, the magnitude of attraction, repulsion, wetting, adsorption, absorption, and combinations thereof between a reactive composition and a first surface and a reactive composition and a second surface differs by about 10% or more, about 20% or more, about 30% or more, about 40% or more, about 50% or more, about 60% or more, about 80% or more, about 100% or more, about 150% or more, about 200% or more, about 250% or more, about 300% or more, about 350% or more, about 400% or more, about 450% or more, about 500% or more, about 600% or more, about 700% or more, about 800% or more, or a bout 900% or more. For example, a heterogeneous stamp or stencil can comprise a first surface having a first functionality and a second surface having a second functionality (i.e., differing chemical functional groups, free energies, hydrophobicity/hydrophilicity, and the like). Differential affinity of a reactive composition for the first and second surfaces of a heterogeneous stamp or stencil of the present invention can arise from a covalent bonding interaction, an ionic interaction, a Van der Waals interaction, a hydrophobic-hydrophobic interaction, a hydrophilic-hydrophilic interaction, a hydrophobic-hydrophilic interaction, a capillary interaction, a size-exclusion interaction, a magnetic interaction, an electrical interaction, and combinations thereof, and any other interactions that can occurs between a surface and a reactive composition (i.e., a solid, liquid, gas, plasma, particulate, colloid, paste, gel, and the like).

Stencils of the present invention include a front surface and back surface, wherein the front surface includes a material having pattern therein that is substantially impermeable to a reactive composition, and wherein the back surface includes a porous membrane that is substantially permeable to a reactive composition. Thus, stencils of the present invention are heterogeneous, for example, due to a difference in permeability of a reactive composition through a back surface and a front surface of a stencil. In some embodiments, a porous membrane is substantially permeable to a reactive composition, and a contact layer is substantially impermeable to a reactive composition.

As used herein, an affinity between a reactive composition and a surface of a heterogeneous stamp or stencil composition can be measured, for example, by a contact angle between the reactive composition and the surfaces, a percentage change in the area of the surfaces upon contacting a reactive composition, a percentage change in the volume enclosed by the surfaces upon contacting a reactive composition, a weight percentage increase in the surfaces upon contacting a reactive composition, the percentage of surface area covered or conformally covered by a reactive composition, and the like, and any other measurements known to persons of ordinary skill in the art of surface morphology, elastomer technology, and the like.

In some embodiments, a heterogeneous stencil refers to a stencil composition in which at least a portion of the openings in the stencil contain therein or thereon a material that is permeable to a reactive composition such that the reactive composition can cross from the backside of the stencil to react with a substrate.

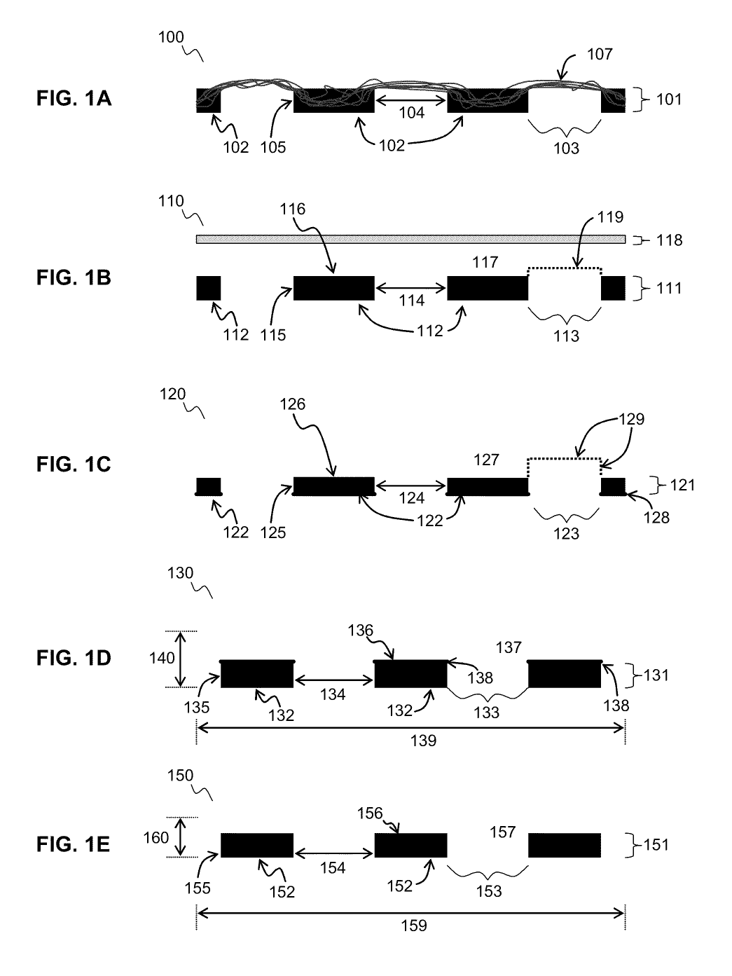

FIG. 1A provides a cross-sectional schematic representation of a heterogeneous stencil of the present invention. Referring to FIG. 1A, stencil 100, comprises a front surface, 102, that includes a contact layer, 101, having at least one opening there through, 103, which provides a pattern with a lateral dimension 104. The opening in the contact layer has a sidewall, 105, and at least a portion of the contact layer, 101, is affixed to a porous membrane, 107. In some embodiments, the porous membrane, 107, comprises a flexible material selected from: a non-woven wire layer, a non-woven fiber layer, a melt-blown polymer layer, a plurality of polymeric and/or metal nanowires (e.g., electrospun nanowires and sintered variants thereof, as provided in U.S. Pat. No. 7,575,707, which is incorporated herein by reference in the entirety), a fabric, a glass and/or metal mesh, a glass and/or metal wool or fiber, and the like, and combinations thereof.

FIG. 1B provides a cross-sectional schematic representation of a heterogeneous stencil of the present invention. Referring to FIG. 1B, stencil 110, comprises a front surface, 112, that includes a contact layer, 111, having at least one opening there through, 113, which provides a pattern with a lateral dimension 114. The opening in the contact layer has a sidewall, 115, and a back surface of the contact layer, 116, is affixed to a porous membrane, 117. In some embodiments, the porous backing layer includes one or more recesses, 119, that are align with the openings in the front surface of the stencil, 113. In some embodiments, a rigid member, 118, is affixed to the porous membrane. A rigid member can be affixed on the periphery of the porous membrane, for example, to one or more of the edges. In some embodiments, a rigid member comprises a webbed or latticed material and is affixed to a back surface of the porous membrane.

FIG. 1C provides a cross-sectional schematic representation of a heterogeneous stencil of the present invention. Referring to FIG. 1C, stencil 120, comprises a front surface, 122, that includes a contact layer, 121, having at least one opening there through, 123, which provides a pattern with a lateral dimension 124. The opening in the contact layer has a sidewall, 125, and a back surface of the contact layer, 126, is affixed to a porous membrane, 127. In some embodiments, an additional layer, 128, is present on the front surface of the stencil, 122. The additional layer can include, but is not limited to, a polymer, an elastomer, a photoimaged polymer, a light-absorbing layer, a light-reflecting layer, an anti-reflective layer, an adhesive, and the like, and combinations thereof. For example, an additional layer can have a predetermined hardness, surface free energy, and the like. In some embodiments, an additional layer present on a front surface of a stencil is suitable for controlling the contact of a front surface of the stencil with a substrate while applying a pressure of about 10 kPa or less to the backside of the stencil and/or the substrate. In some embodiments, the porous backing layer includes one or more recesses, 129, that are align with the openings in the front surface of the stencil, 123.

FIG. 1D provides a cross-sectional schematic representation of a heterogeneous stencil of the present invention. Referring to FIG. 1D, stencil 130, comprises a front surface, 132, that includes a contact layer, 131, having at least one opening there through, 133, which provides a pattern with a lateral dimension 134. The opening in the contact layer has a sidewall, 135, and a back surface of the contact layer, 136, is affixed to a porous membrane, 137. In some embodiments, an additional layer, 138, is present between the contact layer, 131, and the porous membrane. The additional layer can include, but is not limited to, a polymer, an elastomer, a photoimaged polymer, a light-absorbing layer, a light-reflecting layer, an anti-reflective layer, an adhesive, and the like, and combinations thereof. In some embodiments, the porous membrane is sufficiently rigid, 139, such that the surface of the front surface of the stencil, 132, deviates from an average value by about 20% or less of the thickness of the stencil, 140. Thus, a stencil having a thickness of 500 μm would, in some embodiments, exhibit a deviation of about 100 μm or less across the back surface of the stencil (i.e., the level of the back surface of the stencil would vary by about ±50 μm or less across the surface of the stencil).

FIG. 1E provides a cross-sectional schematic representation of a heterogeneous stencil of the present invention. Referring to FIG. 1E, stencil 150, comprises a front surface, 152, that includes a contact layer, 151, having at least one opening there through, 153, which provides a pattern with a lateral dimension 154. The opening in the contact layer has a sidewall, 155, and a back surface of the contact layer, 156, is affixed to a porous membrane, 157. In some embodiments, a portion of the sidewall, 155, is also affixed to the porous membrane, 157, such that at least a portion of the openings in the stencil, 153, contain therein or thereon a material that is substantially permeable to a reactive composition. In some embodiments, the porous membrane is rigid and the front surface of the stencil, 152, has a flatness such that the front surface of the stencil, 152, deviates from an average value by about 20% or less of the thickness of the stencil, 160. Thus, a stencil having a thickness of 100 μm would, in some embodiments, exhibit a deviation of about 20 μm or less across the back surface of the stencil (i.e., the level of the back surface of the stencil would vary by about ±10 μm or less across the surface of the stencil).

The present invention permits a stencil to be used multiple times. Of particular advantage is the ability to re-use stencils having discontinuous surfaces. For example, stencil patterns comprising parallel lines, concentric circles (e.g., “target” shapes), and the like cannot typically be used to pattern more than a single surface because the lateral dimensions of the stencil are destroyed or skewed upon removal of the stencil after patterning a first substrate. However, stencils of the present invention comprising a continuous flexible, permeable material provide a backing having sufficient cohesiveness such that a stencil having discontinuous surfaces can be applied to a first substrate, removed, optionally cleaned, and applied to a second substrate, wherein surface features formed on the first and second substrates using the stencil have lateral dimensions that differ by about 20% or less, about 15% or less, about 10% or less, about 7% or less, about 5% or less, about 3% or less, about 2% or less, or about 1% or less.

Porous membranes for use with the stencils of the present invention include any material having a continuous or partially continuous system of pores. The term “membrane” is used in reference only to a porous material having a thickness that is less than its lateral dimension (e.g., width, diameter, length) and does not limit the porous materials in terms of their flexibility, rigidity, thickness, and the like. Exemplary materials suitable for use as a porous membrane with the present invention include, but are not limited to, a nylon, a polyethersulfone, a polypropylene, a poly(tetrafluoroethylene), a polycarbonate, a cellulose acetate, a sintered plastic, a carbon fiber, a glass fiber, a glass, and a ceramic, and the like, laminates thereof, and composites thereof.

In some embodiments, a porous membrane is rigid. As used herein, “rigid” refers to stiffness or resistance to out-of-plane flexing, and can be approximated by the Young's modulus of a material. Rigid materials suitable for use as a porous membrane with the present invention include, but are not limited to, glasses, ceramics, metals, plastics, and the like, laminates thereof, and composites thereof.

In some embodiments, a rigid porous membrane for use with the present invention has a Young's Modulus of about 10 GPa or higher, about 20 GPa or higher, about 30 GPa or higher, about 40 GPa or higher, about 50 GPa or higher, about 60 GPa or higher, about 70 GPa or higher, or about 80 GPa or higher. In some embodiments, a rigid porous membrane for use with the present invention has a Young's Modulus of about 10 GPa to about 450 GPa, about 20 GPa to about 400 GPa, about 30 GPa to about 350 GPa, about 40 GPa to about 300 GPa, about 50 GPa to about 250 GPa, about 60 GPa to about 200 GPa, about 70 GPa to about 200 GPa, or about 80 GPa 200 GPa.

In some embodiments, a porous membrane has a porosity of about 20% to about 70%, 20% to about 50%, about 25% to about 65%, about 30% to about 60%, about 35% to about 55%, about 40% to about 70%, or about 50% to about 70% by volume.

In some embodiments, a porous membrane has an average pore size of about 100 nm to about 2 mm, about 100 nm to about 1.5 mm, about 100 nm to about 1 mm, about 100 nm to about 500 μm, about 100 nm to about 100 μm, about 100 nm to about 50 μm, about 100 nm to about 10 μm, about 100 nm to about 5 μm, about 100 nm to about 1 μm, about 100 nm to about 500 nm, about 500 nm to about 2 mm, about 500 nm to about 1.5 mm, about 500 nm to about 1 mm, about 500 nm to about 500 μm, about 500 nm to about 100 μm, about 500 nm to about 50 μm, about 500 nm to about 10 μm, about 500 nm to about 5 μm, about 500 nm to about 1 μm, about 1 μm to about 2 mm, about 1 μm to about 1.5 mm, about 1 μm to about 1 mm, about 1 μm to about 500 μm, about 1 μm to about 100 μm, about 1 μm to about 50 μm, about 1 μm to about 10 μm, about 1 μm to about 5 μm, about 5 μm to about 2 mm, about 5 μm to about 1.5 mm, about 5 μm to about 1 mm, about 5 μm to about 500 μm, about 5 μm to about 100 μm, about 5 μm to about 50 μm, about 10 μm to about 2 mm, about 10 μm to about 1.5 mm, about 10 μm to about 1 mm, about 10 μm to about 500 μm, about 10 μm to about 100 μm, about 10 μm to about 50 μm, about 50 μm to about 2 mm, about 50 μm to about 1.5 mm, about 50 μm to about 1 mm, about 50 μm to about 500 μm, about 50 μm to about 100 μm, about 100 μm to about 2 mm, about 100 μm to about 1.5 mm, about 100 lam to about 1 mm, about 100 μm to about 500 μm, about 500 μm to about 2 mm, about 500 μm to about 1.5 mm, about 500 μm to about 1 mm, about 2 μm to about 4 μm, about 220 nm, or about 450 nm. Suitable methods for measuring porosity include, but are not limited to, optical methods, water evaporation methods, mercury intrusion methods, gas expansion methods, PALS, and other analytical methods known to persons of ordinary skill in the art.

In some embodiments, a porous membrane has a thickness of about 50 μm to about 1,000 μm, about 50 μm to about 750 μm, about 50 μm to about 500 μm, about 50 lam to about 250 μm, about 50 μm to about 200 μm, about 50 μm to about 150 μm, or about 50 μm to about 100 μm.

Further exemplary materials suitable for use as a porous membrane with the present invention include, but are not limited to, nylon having a thickness of about 50 μm and a pore size of about 450 nm, sintered plastic membrane having a pore size of about 2 μm to about 4 μm, a porous sintered polycarbonate membrane, a porous glass membrane, and the like.

In some embodiments, a front surface of a stencil for use with the present invention has a flatness of about 20% or less, about 15% or less, or about 10% or less of the stencil thickness. As used herein, flatness refers to deviation in an amplitude of a stencil surface from an average value, and refers to a front surface of a stencil (i.e., the contact layer). Flatness can be determined by profiling a front surface of a stencil using, for example, optical interference methods, an optical flat, a scanning profilometer, and the like. Deviations from an average amplitude of the front surface of the stencil are compared to a value that is 20% of the thickness of the stencil, and in some embodiments the deviations from an average value are about 20% or less than the stencil thickness. Stencil thickness can be measured, for example, using a caliper, a microscope, and the like. Thus, in some embodiments a stencil having a thickness of 100 μm has a front surface that deviates by about ±10 μm or less from an average value (i.e., 100 μm×20%=20 μm).

Not being bound by any particular theory, flatness of stencil can correlate with pattern uniformity across the surface of a substrate, and stencils having a flatness of about 20% or less of the stencil thickness can provide uniform patterns of surface features.

Heterogeneous surface areas of the stamps and/or stencils of the present invention have a boundary there between. In some embodiments, the boundary between heterogeneous surface areas of a stamp comprises a variation in the chemical functional groups on the surface of the stamp or stencil. For example, in some embodiments, a first area of a stamp or stencil surface comprises hydrophobic functional groups, and a second area of the stamp or stencil surface comprises hydrophilic functional groups. Other classes of functional groups suitable for use with the present invention include, but are not limited to, hydrogen-bond donating, hydrogen-bond receiving, halogenated, perhalogenated, hydrolysable functional groups, ionic functional groups, zwitterionic functional groups, and combinations thereof.

A heterogeneous stamp of the present invention comprises two or more surfaces having different functional groups or different classes of functional groups such that a reactive composition applied to the stamp surface has a differential affinity for the heterogeneous areas (i.e., the reactive composition adheres readily to a first area of the stamp and has a lesser affinity to a second area of the stamp).

Chemical functional groups suitable for defining a pattern in the surface of a elastomeric material include, but are not limited to, hydroxyl, alkoxyl, thiol, alkylthio, silyl, alkylsilyl, alkylsilenyl, siloxyl, primary amino, secondary amino, tertiary amino, carbonyl, alkylcarbonyl, aminocarbonyl, carbonylamino, carboxyl, phospho, a polymer, a polymer precursor, a metal, a metal oxide, an organometallic compound, and combinations thereof.

As used herein, “hydroxyl,” by itself or as part of another group, refers to an (—OH) moiety.

As used herein, “alkoxyl,” by itself or as part of another group, refers to one or more alkoxyl (—OR) moieties, wherein R is selected from the alkyl, alkenyl, alkynyl, aryl, aralkyl, and heteroaryl groups described below.

As used herein, “thiol,” by itself or as part of another group, refers to an (—SH) moiety.

As used herein, “alkylthio,” refers to an (—SR) moieties, wherein R is selected from the alkyl, alkenyl, alkynyl, aryl, aralkyl, and heteroaryl groups described below.

As used herein, “silyl,” by itself or as part of another group, refers to an (—SiH₃) moiety.

As used herein, “alkylsilyl,” by itself or as part of another group, refers to an (—Si(R)ₓH_{y}) moiety, wherein 1≦x≦3 and y=3−x, and wherein R is independently selected from the alkyl, alkenyl, alkynyl, aryl, aralkyl, and heteroaryl groups described below.

As used herein, “alkylsilenyl,” by itself or as part of another group, refers to a (—Si(═R)H) moiety, wherein R is selected from the alkyl, alkenyl, alkynyl, aryl, aralkyl, and heteroaryl groups described below.

As used herein, “siloxyl,” by itself or as part of another group, refers to a (—Si(OR)ₓR¹_{y}) moiety, wherein 1≦x≦3 and y=3−x, wherein R and R¹ are independently selected from hydrogen and the alkyl, alkenyl, alkynyl, aryl, aralkyl, and heteroaryl groups described below.

As used herein, “primary amino,” by itself or as part of another group, refers to an (—NH₂) moiety.

As used herein, “secondary amino,” by itself or as part of another group, refers to an (—NRH) moiety, wherein R is selected from the alkyl, alkenyl, alkynyl, aryl, aralkyl, and heteroaryl groups described below.

As used herein, “tertiary amino,” by itself or as part of another group, refers to an (—NRR¹) moiety, wherein R and R¹ are independently selected from the alkyl, alkenyl, alkynyl, aryl, aralkyl, and heteroaryl groups described below.

As used herein, “carbonyl,” by itself or as part of another group, refers to a (C═O) moiety.

As used herein, “alkylcarbonyl,” by itself or as part of another group, refers to a (—C(═O)R) moiety, wherein R is independently selected from hydrogen and the alkyl, alkenyl, alkynyl, aryl, aralkyl, and heteroaryl groups described below.

As used herein, “aminocarbonyl,” by itself or as part of another group, refers to a (—C(═O)NRR¹) moiety, wherein R and R¹ are independently selected from hydrogen and the alkyl, alkenyl, alkynyl, aryl, aralkyl, and heteroaryl groups described below.

As used herein, “carbonylamino,” by itself or as part of another group, refers to a (—N(R)C(═O)R¹) moiety, wherein R and R¹ are independently selected from hydrogen and the alkyl, alkenyl, alkynyl, aryl, aralkyl, and heteroaryl groups described below.

As used herein, “carboxyl,” by itself or as part of another group, refers to a (—COOR) moiety, wherein R is independently selected from hydrogen and the alkyl, alkenyl, alkynyl, aryl, aralkyl, and heteroaryl groups described below.

As used herein, a “phospho,” by itself or as part of another group, refers to a (—P(═O)(OR)(—OR¹) moiety, wherein R and R¹ are independently selected from hydrogen and the alkyl, alkenyl, alkynyl, aryl, aralkyl, and heteroaryl groups described below.

As used herein, a “metal,” by itself or as part of another group, refers to (M), wherein M denotes an element chosen from a transition metal, aluminum, gallium, germanium, indium, tin, antimony, thallium, lead, bismuth, polonium, and combinations thereof.

As used herein, a “metal oxide,” by itself or as part of another group, refers to a (M-Oₓ) moiety, wherein M denotes a metal, as described above, and —Oₓ denotes one or more oxygen atoms bonded to the metal by a single, double, triple, or partial chemical bonds, and wherein x is an integer greater than zero.

As used herein, an “organometallic group,” by itself or as part of another group, refers to a (M-Lₓ) moiety, wherein M denotes a metal, as described above, and -Lₓ denotes a ligand group comprising an alkyl, alkenyl, alkynyl, heteroalkyl, aryl, or heteroaryl group, as defined below. In some embodiments, the ligand further comprises one or more Group 13, Group 14, Group 15, Group 16, Group 17 and/or Group 18 elements that forms a bond with a metal by a single, double, triple, or partial chemical bond, and wherein x is an integer greater than zero. In some embodiments, a ligand group can have more than one bonding interaction with a metal atom or atoms, for example, an organometallic group can comprise a bidentate ligand having two bonds to a metal or metals (e.g., ethylenediamine, acetylacetonate, phenanthroline, and the like), a tridentate ligand having three bonds to a metal or metals (e.g., diethylenetriamine, triazacyclononane, and the like), a tetradentate ligand having four bonds to a metal or metals (e.g., a porphyrin, a corrole, triethylenetetramine, and the like), a pentadentate ligand having five bonds to a metal or metals (e.g., ethylenediaminetriacetate, and the like), a hexadentate ligand having six bonds to a metal or metals (e.g., ethylenediamine tetraacetic acid, and the like), and combinations thereof. Within the scope of the present invention are organometallic groups comprising ligands having two or more bonds to a metal or metals can have a bonding interaction with a single metal atom or several metal atoms. In addition to covalent, ionic, and hydrogen bonds, ligands for use with the present invention can comprise organometallic groups having bonds formed between metal atoms and pi-electrons in carbon-carbon double bonds and/or aromatic rings, and the like (e.g., cyclopentadiene, ethylene, etc.).

As used herein, a “polymer” refers to a group comprising two or more repeating units that are bonded together by a covalent, a hydrogen, and/or an ionic bond, or a combination thereof. Polymers for use with the present invention can be isotactic, atactic, or syndiotactic. Polymers for use with the present invention can be linear, branched, cross-linked, cyclic, and combinations thereof. In some embodiments, a polymer for use with the present invention is an elastomer. In some embodiments, a polymer is present in a coating layer applied to a master, or in a coating layer applied to an elastomeric stamp.

As used herein, a “polymer precursor” refers to a oligomer, monomer, or other moiety that can react with another oligomer, monomer, or other moiety, or with itself, to produce a polymer.

In some embodiments, the chemical functional group can be bound directly to the surface of the elastomeric stamp. In some embodiments, a linker group can separate the chemical functional group from the surface of the elastomeric stamp. Suitable linker groups include, but are not limited to, alkyl, alkenyl, alkynyl, heteroalkyl, aryl, aralkyl, and heteroaryl.

As used herein, “alkyl,” by itself or as part of another group, refers to straight chain, branched chain, cyclic, and bicyclic hydrocarbons of up to 20 carbon atoms, such as, but not limited to, octyl, decyl, dodecyl, hexadecyl, octadecyl, and cyclohexyl.

As used herein, “alkenyl,” by itself or as part of another group, refers to a straight chain, branched chain, cyclic, and bicyclic hydrocarbons of up to 20 carbon atoms, wherein there is at least one double bond between two of the carbon atoms in the chain and/or ring(s), and wherein the double bond can be in either of the cis or trans configurations, including, but not limited to, 2-octenyl, 1-dodecenyl, 1-8-hexadecenyl, 8-hexadecenyl, and 1-octadecenyl, and cyclohexenyl.

As used herein, “heteroalkyl,” by itself or as part of another group, refers to alkyl groups as defined above, wherein the atoms in the chain and/or ring(s), in addition to carbon, include at least one heteroatom. The term “heteroatom” is used herein to mean an oxygen atom (“O”), a sulfur atom (“S”) or a nitrogen atom (“N”). Additionally, the term heteroalkyl also includes N-oxides of heteroalkyl species that containing a nitrogen atom in the chain and/or ring.

As used herein, “aryl,” by itself or as part of another group, refers to cyclic, fused cyclic, and multi-cyclic aromatic hydrocarbons containing up to 20 carbons in the ring portion. Typical examples include phenyl, naphthyl, anthracenyl, fluorenyl, tetracenyl, pentacenyl, hexacenyl, perylenyl, terylenyl, quaterylenyl, coronenyl, and fullerenyl.

As used herein, “aralkyl” or “arylalkyl,” by itself or as part of another group, refers to alkyl groups as defined above having at least one aryl substituent, such as benzyl, phenylethyl, and 2-naphthylmethyl. Similarly, the term “alkylaryl,” as used herein by itself or as part of another group, refers to an aryl group, as defined above, having an alkyl substituent, as defined above.

As used herein, “heteroaryl,” by itself or as part of another group, refers to cyclic, fused cyclic and multicyclic aromatic groups containing up to 60 atoms in the ring portions, wherein the atoms in the ring(s), in addition to carbon, include at least one heteroatom. The term “heteroatom” is used herein to mean an oxygen atom (“O”), a sulfur atom (“S”) or a nitrogen atom (“N”). Additionally, the term heteroaryl also includes N-oxides of heteroaryl species that containing a nitrogen atom in the ring. Typical examples include pyrrolyl, pyridyl, pyridyl N-oxide, thiophenyl, and furanyl.

In some embodiments, the boundary between heterogeneous surface areas of the elastomeric stamp further comprises a topographical variation in the surface of the elastomeric material. For example, a stamp can have at least one indentation in its surface defining a pattern therein, wherein the composition of the surface of the at least one indentation differs from the composition of the surface of the stamp suitable for conformally contacting a substrate.

In some embodiments, the heterogeneous stamp composition further comprises a reservoir configured to receive a reactive composition, wherein the reservoir is in fluid communication with a pattern in the surface of the elastomeric material. As used herein, a “reservoir” refers to an enclosed or partially enclosed volume suitable for receiving a reactive composition.

In some embodiments, a reservoir comprises a porous structure of an elastomeric material. A reactive composition can be added to the porous structure of the elastomeric material and move from the porous structure to a surface of the stamp as needed during a printing process. For example, a reactive composition can be adsorbed or injected into a largely continuous, open pore structure of a porous elastomer. In some embodiments, an external stimulus (e.g., pressure, a voltage gradient, a magnetic field, gravity, and the like) or a property of the stamp (e.g., surface functionalization, shape, and the like) can induce a reactive composition to flow from the pore structure of the elastomer to a surface of the stamp or stencil, thereby wetting the surface of the stamp or stencil without directly applying a reactive composition.

In some embodiments, a reservoir comprises a volume enclosed between the surface of the elastomeric stamp and a peelable layer thereon.

In some embodiments, a stamp or stencil further comprises a rigid or semi-rigid support layer applied to a surface of the elastomeric stamp or stencil opposite to the surface comprising heterogeneous areas. As used herein, a rigid or semi-rigid support refers to an element that can be applied to the backside of a stamp or stencil, or embedded in, or otherwise bound to, the elastomeric material of a stamp or stencil that lends structural support to the stamp or stencil. Typically, a rigid or semi-rigid support has a higher modulus than the elastomeric material. In some embodiments, the rigid or semi-rigid support has a thickness greater than the elastomeric material. Materials suitable for use as rigid or semi-rigid supports include, but are not limited to, a metal, a ceramic, fibrous materials (e.g., cloth, wood, mesh, and the like), a polymeric material (e.g., a polyvinylchloride, mylar, a polycarbonate, a polyurethane, and the like), and combinations thereof.

In some embodiments, the stamp or stencil of the present invention further comprises a protective layer adhered or otherwise bound to a backside of the elastomeric stamp or stencil. In some embodiments, a peelable protective layer is applied to the backside of the stamp or stencil. Not being bound by any particular theory, a protective layer can prevent a reactive composition from drying during storage, prevent the stamp or stencil from undergoing distortion during storage, and/or otherwise protect the stamp or stencil from damage prior or during use.

In some embodiments, a stamp or stencil of the present invention further comprises a porous layer positioned between the surface of an elastomeric stamp and a rigid or semi-rigid support layer, wherein the porous layer is configured to receive a reactive composition and is in fluid communication with a heterogeneous surface on the face of the elastomeric stamp or stencil. For example, a stamp of the present invention can include a front surface comprising an elastomeric material, and having positioned on the backside of the elastomeric material a porous layer suitable for receiving a reactive composition. In some embodiments, the reactive composition contained within the porous layer can permeate slowly through the elastomeric material to the front surface of the stamp. A heterogeneous surface of the stamp defines the pattern that is transferred from a stamp to a substrate.

In some embodiments, the openings of a heterogeneous stencil of the present invention are filled with a porous material. Porous materials suitable for filling the openings of a stencil of the present invention can comprise a gel, fiber, colloid, glass, or any other material having a continuous network of pores in which a reactive composition can be retained and/or pass through.

In some embodiments, a heterogeneous stencil of the present invention comprises a flexible permeable material bound to at least a portion of the elastomeric material of the stencil, wherein the flexible permeable material that provides a continuous layer on the back surface of the elastomeric material.

Flexible, permeable materials suitable for use with the present invention include, but are not limited to materials chosen from poly(para-phenyleneterephthalamide) (e.g., KEVLAR®, E.I. du Pont de Nemours and Co., Wilmington, Del.), poly(meta-phenyleneterephthalamide) (e.g., NOMEX®, E.I. du Pont de Nemours and Co., Wilmington, Del.), a carbon fiber (e.g., a mat and/or a veil comprising carbon fiber), a glass fiber (e.g., a mat or a veil comprising glass fiber), a polycarbonate (e.g., woven and/or fibrous polycarbonate), a poly(ethersulfone), a poly(ethylene naphthalate), a poly(ethylene terephthalate) (e.g., MYLAR®, E.I. du Pont de Nemours and Co., Wilmington, Del.), a nitrocellulose, nylon 6-6, nylon 6, nylon 9, nylon 5-10, nylon 6-12, and combinations thereof. The flexible, permeable material can comprise a filamentous material, a layered material, a woven material, a polymeric material, and combinations thereof.

In some embodiments, a flexible porous membrane is a material that does not readily undergo longitudinal deformation (i.e., stretching in the plane of a sheet), but that can be repeatedly rolled, bent, folded, and the like without undergoing plastic deformation.

In some embodiments, a flexible porous membrane comprises individual fibers that, for example, are glued, woven, adhered, or otherwise held together to form a veil. In some embodiments, a flexible porous membrane is covalently bound to the stencil. In some embodiments, a flexible porous membrane can be removed from the stencil after the stencil is applied to a substrate.

In some embodiments, a porous membrane is further positioned in or on an opening in the stencil, wherein the porous membrane is permeable to a reactive composition suitable for reacting with a substrate.

Not being bound by any particular theory, a porous membrane permits stencils having discontinuities to be used to pattern more than one substrate. Typically, discontinuous stencils that comprise distinct regions that are not physically connected to one another can be applied to a substrate using, for example a membrane that retains the spatial dimensions of the stencil during the applying of the stencil to a substrate. After applying the stencil to a substrate the backing layer is then typically removed and the substrate is patterned. However, removal of the stencil from the substrate results in a loss of pattern dimensions and the stencil can only be used to pattern a single substrate. Conversely, the porous membrane bound to the stencil (e.g., the backside of the stencil) enables a stencil of the present invention to be applied to a substrate, patterning of the substrate to occur (e.g., by applying a reactive composition to the substrate through the porous membrane), and then removed from the substrate, optionally cleaned, and then applied to a second substrate.

Stamps and stencils of the present invention include an indentation or opening in a surface of the stamp or stencil, respectively, having at least one lateral dimension of about 100 μm or less. In addition to an indentation or opening having at least one lateral dimension of about 100 μm or less, the stamps and stencils of the present invention can also include indentations and openings having larger lateral dimensions (i.e., patterns formed using the stamps and stencils of the present invention have at least one lateral dimension of about 100 μm or less, but can also include regions of a pattern having In some embodiments, a stamp or stencil of the present invention includes an indentation or opening in the surface of the stamp or stencil having a minimum lateral dimension of about 80 μm or less, about 50 μm or less, about 20 μm or less, about 15 μm or less, about 10 μm or less, about 8 μm or less, about 5 μm or less, about 1 μm or less, or about 0.5 μm or less. In some embodiments, a stamp or stencil of the present invention includes an indentation or opening in the surface of the stamp or stencil having a minimum lateral dimension of about 0.04 μm to about 100 μm, about 0.05 μm to about 90 μm, about 0.08 lam to about 80 μm, about 0.1 μm to about 50 μm, about 0.5 μm to about 30 μm, about 0.1 μm to about 20 μm, about 0.1 μm to about 10 μm, about 0.1 μm to about 5 μm, or about 0.1 μm to about 1 μm.

Furthermore, a first and second patterns in the heterogeneous stamps of the present invention can have different depths. For example, a first pattern can have a depth that is constant or varies across the first surface. In some embodiments, the at least one indentation has a depth not greater than about 100 times, about 80 times, about 50 times, about 40 times, about 30 times, about 20 times, about 15 times, about 10 times, about 5 times, about 4 times, about 3 times, about 2 times, about 1.5 times, or about equal to the magnitude of a lateral dimension defined by the at least one indentation.

In some embodiments, a stencil of the present invention has a thickness not greater than about 10 times, about 8 times, about 5 times, about 4 times, about 3 times, about 2 times, about 1.5 times, or about equal to the minimum lateral dimension of the at least one opening.

In some embodiments, a surface of an elastomeric stamp or stencil suitable for conformally contacting a substrate has a surface area of about 500 mm² or more, about 1,000 mm² or more, about 5,000 mm² or more, about 10,000 mm² or more, about 20,000 mm² or more, about 50,000 mm², about 75,000 mm² or more, about 100,000 mm² or more, or about 150,000 mm² or more.

In some embodiments, the elastomeric stamp or stencil further comprises a removable protective sheet adhered to the front surface of the elastomer (i.e., the “front” surface being that which is suitable for conformally contacting a substrate). For example, a removable protective sheet can comprise a thin plastic sheet adhered to the front of the elastomeric stamp using, for example, a pressure-sensitive or water-soluble adhesive. The protective sheet can prevent the stamp or stencil from becoming damaged during storage, and can also prevent degradation (e.g., oxidation) of the front surface of the elastomeric material, or degradation of a reactive composition contained within the indentations or openings of an elastomeric stamp or stencil.

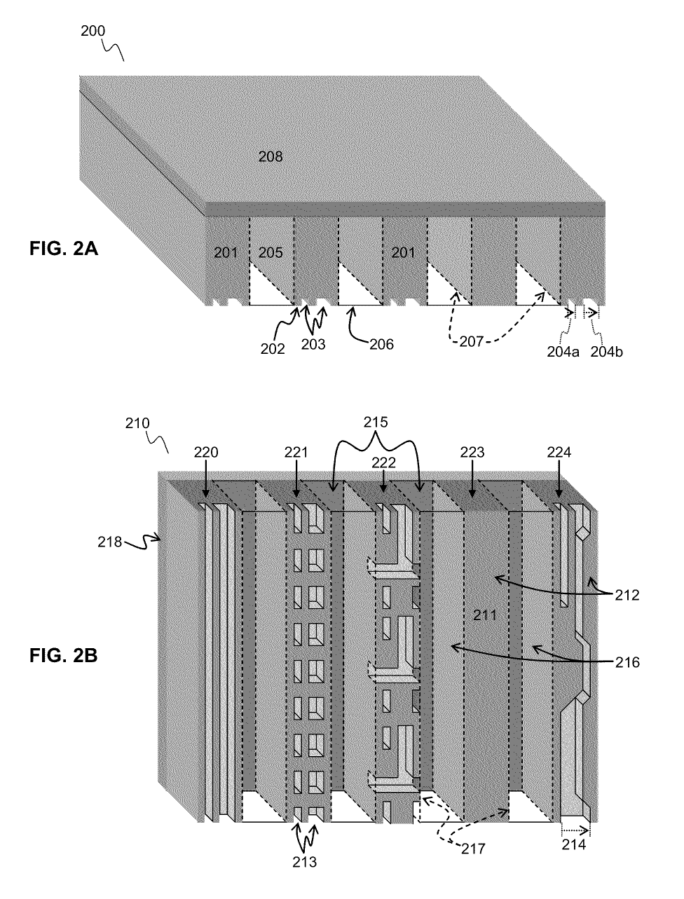

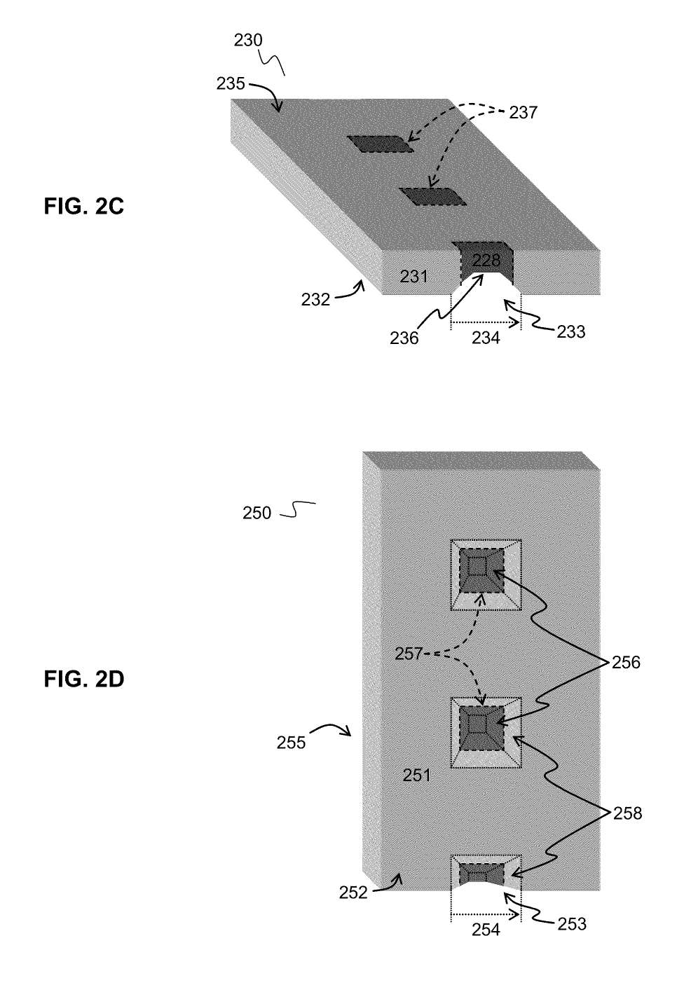

FIGS. 2A and 2B depict a three-dimensional schematic representation of an embodiment of the present invention. Referring to FIG. 2A, provided is a three-dimensional schematic representation showing the top and sides of a heterogeneous stamp composition, 200, having a first surface, 202, comprising an elastomeric material, 201, and including at least one indentation therein, 203. At least one indentation in the surface of the elastomer has a lateral dimension, 204a or 204b, of about 100 μm or less. The heterogeneous stamp composition further comprises a second surface, 206, that is adjacent to the first surface and having a boundary, 207, there between. The second surface comprises a material, 205, such that a reactive composition deposited onto the first and second surfaces has a differential affinity for the first and second surfaces. In some embodiments, the heterogeneous stamp further comprises a rigid or semi-rigid backing layer, 208.

Referring to FIG. 2B, provided is a three-dimensional schematic representation showing the bottom and sides of a heterogeneous stamp composition, 210, having a first surface, 212, comprising an elastomeric material, 211, and including at least one indentation therein, 213. At least one indentation in the surface of the elastomer has a lateral dimension, 214, of about 100 μm or less. The heterogeneous stamp composition further comprises a second surface, 216, that is adjacent to the first surface and having a boundary, 217, there between. The second surface comprises a material, 215, such that a reactive composition deposited onto the first and second surfaces has a differential affinity for the first and second surfaces. In some embodiments, the heterogeneous stamp further comprises a rigid or semi-rigid backing layer, 218.

Referring to FIG. 2B, the at least one indentation, 213, in the first surface, 212, forms a first pattern. By way of example only, and without limitation, representative patterns include, but are not limited to, 220 (patterns comprising continuous channels across or through a surface or surfaces of the stamp), 221, (patterns comprising discontinuous channels across or through a surface of surfaces of the stamp), 222 (patterns comprising asymmetric channels and discontinuities in the surface of the stamp), 223 (patterns comprising regions of the surface having no pattern therein), and 224 (patterns comprising serpentine or winding channels and like), and combinations thereof. It is also within the scope of the present invention that the patterns cross the first and second surfaces, or that a boundary between the first and second surfaces overlap with the pattern defined by the at least one indentation.

FIGS. 2C and 2D depict a three-dimensional schematic representation of an embodiment of the present invention. Referring to FIG. 2C, provided is a three-dimensional schematic representation showing the top and sides of a heterogeneous stamp composition, 230, having a first surface, 232, comprising an elastomeric material, 231, and including at least one indentation therein, 233. At least one indentation in the surface of the elastomer has a lateral dimension, 234, of about 100 μm or less. The heterogeneous stamp composition further comprises a second surface, 236, that is adjacent to the first surface and having a boundary, 237, there between. The second surface comprises a material, 238, such that a reactive composition deposited onto the first and second surfaces has a differential affinity for the first and second surfaces. In some embodiments, the heterogeneous stamp further comprises a back surface, 235, that is opposite at least one of the first and second surface having patterns therein.

Referring to FIG. 2D, provided is a three-dimensional schematic representation showing the bottom and sides of a heterogeneous stamp composition, 250, having a first surface, 252, comprising an elastomeric material, 251, and including at least one indentation therein, 253. At least one indentation in the surface of the elastomer has a lateral dimension, 254, of about 100 μm or less. The heterogeneous stamp composition further comprises a second surface, 256, that is adjacent to the first surface and having a boundary, 257, there between. The heterogeneous stamp composition comprises a first pattern, 258, including at least one indentation having a lateral dimension, 254, of about 100 μm or less. The heterogeneous stamp composition further comprises a second surface, 256, in which a boundary, 257, separates the first and second surfaces. The second surface thus defines a second pattern in the heterogeneous stamp composition, as shown by the dashed lines in FIG. 2D (- - - - - -). In FIG. 2D, the second pattern, spatially overlaps the first pattern such that all dimensions of the second pattern are surrounded by the first pattern. This can be contrasted with the heterogeneous stamp composition depicted in FIG. 2B, in which the first patterns, 220, 221, 222, 223 and 224, were spatially adjacent to, but did not overlap with, the second pattern defined by the second surface, 226.

### Methods of Preparing the Stamps and Stencils

The present invention is also directed to a method of preparing a heterogeneous elastomeric stamp composition, the method comprising:
(a) providing a master having a protrusion thereon having a minimum lateral dimension of about 100 μm or less, wherein the surface of the protrusion has a composition and/or functionality different than the surface of the master surrounding the protrusion;
(b) depositing onto the master an elastomeric precursor, wherein the elastomeric precursor covers the protrusion and the surface of the master surrounding the protrusion;
(c) curing the elastomeric precursor to form an elastomer, wherein the elastomer adheres to the protrusion to form a heterogeneous elastomeric stamp composition; and
(d) removing the heterogeneous elastomeric stamp composition from the master, wherein the removing detaches the protrusion from the master.

The present invention is also directed to a method of preparing a heterogeneous elastomeric stamp composition, the method comprising:
(a) providing a master having a protrusion thereon having a minimum lateral dimension of about 100 μm or less, wherein the surface of the protrusion has a composition and/or functionality different than the surface of the master surrounding the protrusion;
(b) disposing onto the master a coating layer, wherein the coating layer is disposed selectively onto either the surface of the protrusion or the surface of the master surrounding the protrusion;
(c) depositing onto the master an elastomeric precursor, wherein the elastomeric precursor covers coating layer, the protrusion, and the surface of the master surrounding the protrusion;
(d) curing the elastomeric precursor to form an elastomer, wherein the elastomer adheres to the coating layer to form a heterogeneous stamp composition; and
(e) removing the heterogeneous stamp composition from the master.

As used herein, a “master” refers to a template suitable for manufacturing an elastomeric stamp or stencil. Masters for use with the present invention include a surface having at least one protrusion thereon. Masters for use with the present invention are not particularly limited by geometry, and can be flat, curved, smooth, rough, wavy, and combinations thereof. Masters are not particularly limited by composition. In some embodiments, masters for use with the present invention are non-porous solids. However, porous solids, flexible solids (e.g., elastomers), deformable solids, and the like can be used as masters with the present invention. Materials suitable for use as masters include any materials that do not form a bond with an elastomeric material or an elastomeric precursor (i.e., it should be possible to remove the elastomeric stamp from the master). Materials suitable for use as masters include, but are not limited to, metals, metal oxides, alloys, composites, crystalline materials, amorphous materials, conductors, semiconductors, glasses, ceramics, plastics, laminates, polymers, minerals, and combinations thereof. In some embodiments, a material suitable for use as a master can be selected based upon one or more of its physical properties, electrical properties, optical properties, thermal properties, and combinations thereof. Masters can be prepared using traditional lithographic processes, ion-beam etching processes, and the like.

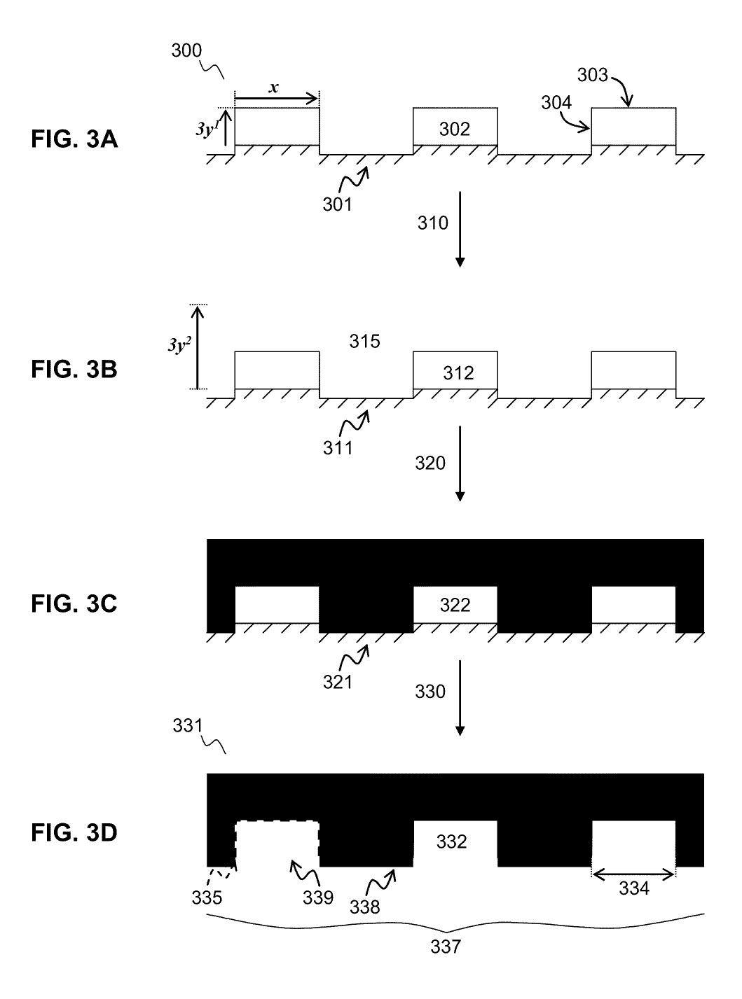

FIGS. 3A-3D provide a cross-sectional schematic representation of a process for preparing a heterogeneous stamp of the present invention. Referring to FIG. 3, a master, 300, including a surface, 301, having at least one protrusion, 302, thereon is provided. The protrusion has a top surface, 303, and a side surface, 304. The at least one protrusion, 302, can have any shape (as viewed from above), including symmetric and asymmetric shapes, rectilinear and curved shapes, and combinations thereof. In some embodiments, a pattern can be formed by repeating the at least one protrusion across the surface of the master.

The protrusion can be made of the same or a different material as the master. In some embodiments, the master and protrusion comprise a monolith. In some embodiments, the protrusion comprises a material that is deposited onto the master and then patterned.

The protrusion has a minimum lateral dimension of about 100 μm or less. As used herein, a “lateral dimension” refers to a dimension of a protrusion that is measured in the plane of the master (for a master having a planar surface), or along the curvature of the surface of the master (for a non-planar master). One or more lateral dimensions of a protrusion define, or can be used to define, the size and shape of an opening that is formed in the elastomeric stamp. Typical lateral dimensions of protrusions include, but are not limited to: length, width, radius, diameter, and combinations thereof. Referring to FIG. 3A, a lateral dimension of a protrusion having a rectilinear shape on a planar master can be determined by the magnitude of one or more vectors lying in the plane of the master that connect points lying on opposite sides of the protrusion (i.e., the protrusion, 302, has a lateral dimension, x). The top surface of the protrusion, 303, can be flat, (as shown in FIG. 3A), convex, concave, angled, pocked, textured, and combinations thereof.

At least one of the lateral dimensions of a protrusion is about 100 μm or less. For a master having more than one protrusion, at least one of the lateral dimensions of at least one of the protrusions has a lateral dimension of about 100 μm or less (i.e., for a master having more than one protrusion, not every protrusion must have a minimum lateral dimension of about 100 μm or less).

Referring to FIG. 3A, the protrusion, 302, has an elevation (i.e., a height), 3y¹, that can be determined by the magnitude of a vector orthogonal to the surface of the master connecting the base of the protrusion with the highest point on the protrusion.

In some embodiments, after providing the master having a protrusion thereon, an elastomeric precursor is applied to the master, 310.

Referring to FIG. 3B, an elastomeric precursor, 315, is applied to the master, wherein the elastomeric precursor is applied to a depth, 3y², sufficient to coat both the surface of the master, 311, and the protrusion, 312. Processes suitable for depositing the elastomeric precursor include, but are not limited to, spin-coating, spraying, ink jet depositing, atomizing, chemical vapor depositing, and combinations thereof. While a blanket deposition is depicted in FIG. 3B, the present invention also contemplates the utilization of a conformal deposition process (e.g., plasma enhanced chemical vapor deposition, hot wire chemical vapor deposition, thermal deposition, and combinations thereof).

In some embodiments, the process comprises curing the elastomeric precursor to provide an elastomer, 320.

Referring to FIG. 3C, an elastomer, 326, covering the surface of the master, 321, and the protrusion, 322, is provided. Furthermore, the elastomer is adhered to the surface of the protrusion. For example, in some embodiments, a functional group on the protrusion can react or interact with a group present in the elastomeric precursor and/or elastomer to form, for example, a covalent bond between the elastomer and the surface of the protrusion, an ionic bond between the elastomer and the surface of the protrusion, a hydrogen bond between the elastomer and the surface of the protrusion, or any other bonding or non-bonding interaction that provides for an adhesive force. The adhering of the elastomer to the surface of the protrusion can occur during the curing, simultaneous with the curing (i.e., one energy source is utilized for the curing and a second energy source provides for the adhering), or after the curing (i.e., the elastomeric precursor is cured to provide an elastomer, which is subsequently reacted with the surface of the protrusion to become adhered thereto). In some embodiments, the elastomeric precursor can be partially cured, followed by a second process that both fully cures the elastomer and adheres the elastomer to the surface of the protrusion.

In some embodiments, the process comprises removing the heterogeneous elastomeric stamp from the surface of the master, 330. The heterogeneous elastomeric stamp can be conformally contacted with any variety of substrates to produce a pattern thereon having a lateral dimension defined by the indentation.

Referring to FIG. 3D, the heterogeneous elastomeric stamp, 331, comprises an elastomer, 336, having an indentation therein, 335, the indentation defining a pattern in the surface of the stamp, 337. The indentation, 337, is filled with a composition defined by the composition of the at least one protrusion on the surface of the master, 332. In some embodiments, the pattern comprises two or more areas of the surface that have a different composition and/or surface functional group. For example, the heterogeneous surface, 337, comprises the surface of the elastomer, 338, having a pattern therein. In some embodiments, the boundary of the pattern is defined by the exposed surface area, 339 (i.e., the surface area on the outer face of the stamp, 337, and not an internal surface area defined in part by the dimensions of the indentation, 335). The exposed surface area, 339, has a lateral dimension, 334, defined by the heterogeneous region of the surface of the elastomeric stamp.

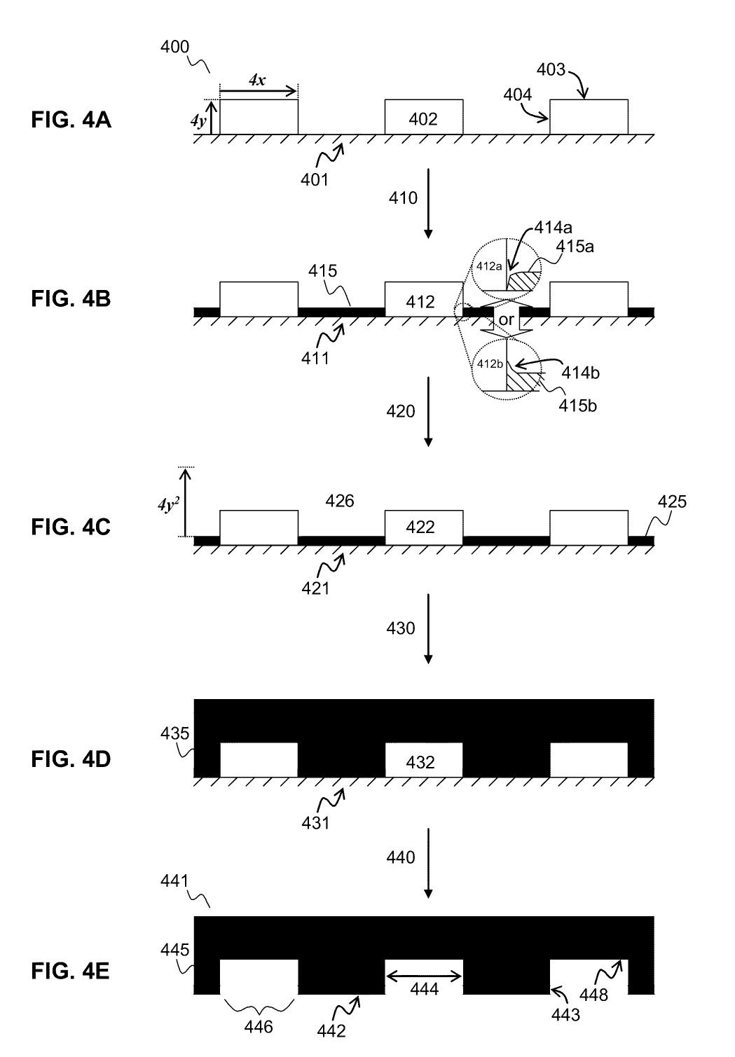

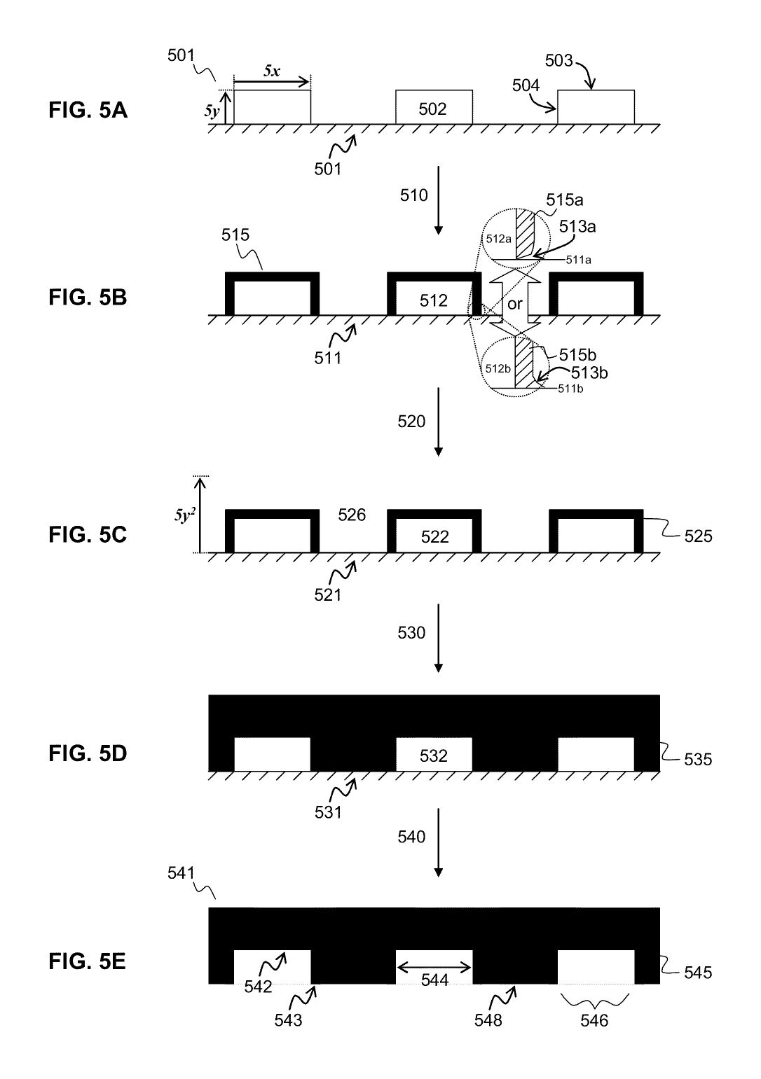

FIGS. 4A-4E and 5A-5E provide a cross-sectional representation of methods of preparing heterogeneous elastomeric stamp compositions, the methods comprising:
(a) providing a master having a protrusion thereon having a minimum lateral dimension of about 100 μm or less, wherein the surface of the protrusion has a composition and/or functionality different than the surface of the master surrounding the protrusion;
(b) disposing onto the master a coating layer, wherein the coating layer is disposed selectively onto either the surface of the protrusion or the surface of the master surrounding the protrusion;
(c) depositing onto the master an elastomeric precursor, wherein the elastomeric precursor covers coating layer, the protrusion, and the surface of the master surrounding the protrusion;
(d) curing the elastomeric precursor to form an elastomer, wherein the elastomer adheres to the coating layer to form a heterogeneous stamp composition; and
(e) removing the heterogeneous stamp composition from the master.

FIGS. 4A-4E provide a cross-sectional schematic representation of a process for preparing an elastomeric stamp of the present invention. Referring to FIG. 4A, a master, 400, including a surface, 401, having at least one protrusion, 402, thereon is provided. The at least one protrusion, 402, includes a top surface, 403, and a side surface, 404, having a lateral dimension, 4x, and an elevation, 4y, respectively, as defined above.

A coating layer is then disposed onto the master, 410. Suitable processes for applying the coating layer to the master include, but are not limited to, spin-coating, spraying, ink jet depositing, atomizing, chemical vapor depositing, atomic layer depositing, sputtering, electroplating, and combinations thereof. In some embodiments, the depositing comprises a self-aligned deposition process whereby the coating layer is deposited selectively onto the master, while substantially avoiding deposition of the coating layer on the protrusion. For example, the master can comprise, or be derivatized with, a chemical functional group suitable for reacting with, or being readily wetted by, a coating material chosen from a polymer, a polymer precursor, a metal, a metal oxide, an organometallic compound, a ceramic, and combinations thereof. In some embodiments, the master can comprise a material, or be pre-treated to provide a surface, that is not be readily wetted by a coating material. After applying the coating material to the master and the protrusion, excess coating material can be removed selectively from the surface of the protrusion without substantially affecting the coating material deposited upon the surface of the master. In some embodiments, a coating comprises a metal foil, a metal colloid, a metal oxide layer, a microparticulate (e.g., a composition comprising particles having a diameter of about 100 nm to about 1,000 μm), a nanoparticulate (e.g., a composition comprising particles having a diameter of about 2 nm to about 100 nm), an aerosol, an electroplated metal coating, an electrolessly deposited metal coating, a polymer, a polymer precursor, and combinations thereof. In some embodiments, a coating layer comprises a functional groups chosen from hydroxyl, alkoxyl, thiol, alkylthio, silyl, alkylsilyl, alkylsilenyl, siloxyl, primary amino, secondary amino, tertiary amino, carbonyl, alkylcarbonyl, aminocarbonyl, carbonylamino, carboxyl, phospho, and combinations thereof, as defined above.

In some embodiments, a coating can be selectively deposited onto the master, a protrusion on the master, an elastomeric stamp, or an indention in the surface of an elastomeric stamp via ink jet printing, stenciling, soft lithography, photolithography, or any other patterning process known to a person of ordinary skill in the art.

In some embodiments, a coating can be selectively deposited onto the master, a protrusion on the master, an elastomeric stamp, or an indentation in the surface of an elastomeric stamp via a self aligned deposition process that employs aerosol deposition, atomic layer deposition, plasma-enhanced chemical vapor deposition, thermal deposition, hot wire deposition, atmospheric plasma deposition, sputtering, and combinations thereof.

Referring to FIG. 4B, structure is provided comprising a coating layer, 415, deposited on the surface of the master, 411, while the protrusion, 412, is substantially free from the coating layer. In some embodiments, the coating layer, 415a, forms an interface, 414a, with the side of the protrusion, 412a, due to a repellent property between the coating layer and the surface the protrusion (e.g., a functional group that makes the surface of the protrusion non-wetting to the coating layer). In some embodiments, the coating layer, 415b, forms an interface, 414b, with the side of the protrusion, 412b, due to a wettable non-adhesive property between the coating layer and the surface the protrusion (e.g., a functional group that makes the surface of the protrusion wettable, but which prevents the coating layer from adhering to the entire surface of the protrusion).

In some embodiments, the process comprises depositing an elastomeric precursor onto the master, 420.

Referring to FIG. 4C, an elastomeric precursor, 426, covering the surface of the master, 421, the protrusion, 422, and the coating layer, 425, is provided. The elastomeric precursor is deposited to provide an elastomeric coating thickness, 4y².

In some embodiments, the process comprises curing the elastomeric precursor to provide an elastomer, 430.

Referring to FIG. 4D, a heterogeneous stamp comprising an elastomer, 437, and a coating layer, 435, is provided. The heterogeneous stamp is formed over the surface of the master, 431, and the at least one protrusion, 432. In some embodiments, curing comprises adhering the elastomer to the coating layer. For example, in some embodiments, a functional group of the elastomer can react or interact with a group present in the coating layer to form, for example, a covalent bond between the elastomer and the coating layer, an ionic bond between the elastomer and coating layer, a hydrogen bond between the elastomer and the coating layer, or any other bonding or non-bonding interaction that provides for an adhesive force. The adhering of the elastomer to the coating layer can occur during the curing, simultaneous with the curing (i.e., one energy source is utilized for the curing and a second energy source provides for the adhering), or after the curing (i.e., the elastomeric precursor is cured to provide an elastomer, which is subsequently reacted with the coating layer to become adhered thereto). In some embodiments, the elastomeric precursor can be partially cured, followed by a second process that both fully cures the elastomer and adheres the elastomer to the coating layer.

In some embodiments, the process comprises removing the heterogeneous elastomeric stamp from the surface of the master, 440.

Referring to FIG. 4E, the heterogeneous elastomeric stamp, 441, comprises an elastomer, 447, having an indentation therein, 446, the indentation defining a pattern in the surface of the stamp. In some embodiments, the pattern has a lateral dimension defined by a lateral dimension of the at least one protrusion, 444. In some embodiments, the pattern in the stamp comprises two or more areas of the surface having a different composition and/or surface functional group. For example, the heterogeneous surface can comprise an elastomer surface, 448, and the surfaces, 442 and 443, of a coating layer, 445. The properties of surfaces 442 and 443 can be the same or different. In some embodiments, a boundary between different areas of the heterogeneous areas of the surface is defined by the lateral dimension of a protrusion.

FIGS. 5A-5E provide a cross-sectional schematic representation of a process for preparing an elastomeric stamp of the present invention. Referring to FIG. 5A, a master, 300, including a surface, 301, having at least one protrusion, 502, thereon is provided. The at least one protrusion, 502, includes a top surface, 503, and a side surface, 504, having a lateral dimension, 5x, and an elevation, 5y, respectively, as defined above.

A coating layer is then disposed onto the protrusion, 510. Suitable processes for applying the coating layer to the master include those listed above, or any other application process known to those of ordinary skill in the art. In some embodiments, the depositing comprises a self-aligned deposition process whereby the coating layer is deposited selectively onto the protrusion, while substantially avoiding deposition of the coating layer on the master. For example, the protrusion can comprise, or be derivatized with, a chemical functional group suitable for reacting with, or being readily wetted by, a coating material chosen from a polymer, a polymer precursor, a metal, a metal oxide, an organometallic group, a ceramic, and combinations thereof. In some embodiments, the master can comprise a material, or be pre-treated to provide a surface, that cannot be readily wetted by a coating material. After applying the coating material to the master and the protrusion, excess coating material can be removed selectively from the surface of the master without substantially affecting the coating material deposited upon the surface of the protrusion.

Referring to FIG. 5B, structure is provided comprising a coating layer, 515, deposited on the surface of the protrusion, 512, while the master, 511, is substantially free from the coating layer. In some embodiments, the coating layer, 515a, deposited on the protrusion, 512a, forms an interface, 513a, with the surface of the master, 511a, due to a repellent property between the coating layer and the surface of the master (e.g., a functional group that makes the surface of the master non-wetting to the coating layer). In some embodiments, the coating layer, 515b, deposited on the protrusion, 512b, forms an interface, 513b, with the surface of the master, 511b, due to a wettable non-adhesive property between the coating layer and the surface of the master (e.g., a functional group that makes the surface of the master wettable, but which prevents the coating layer from adhering to the surface of the master).

In some embodiments, the process comprises depositing an elastomeric precursor onto the master, 520.

Referring to FIG. 5C, an elastomeric precursor, 526, covering the surface of the master, 521, the protrusion, 522, and the coating layer, 525, is provided. The elastomeric precursor is deposited to provide an elastomeric coating thickness, 5y².

In some embodiments, the process comprises curing the elastomeric precursor to provide an elastomer, 530.

Referring to FIG. 5D, a heterogeneous stamp comprising an elastomer, 537, and a coating layer, 535, is provided. The heterogeneous stamp is formed over the surface of the master, 531, and the at least one protrusion, 532. In some embodiments, curing comprises adhering the elastomer, 537, to the coating layer, 535, as described above.

In some embodiments, the process comprises removing the heterogeneous elastomeric stamp from the surface of the master, 540.

Referring to FIG. 5E, the heterogeneous elastomeric stamp, 541, comprises an elastomer, 547, having an indentation therein, 546, the indentation defining a pattern in the surface of the stamp. In some embodiments, the pattern has a lateral dimension defined by a lateral dimension of the at least one protrusion, 544. In some embodiments, the pattern in the stamp comprises two or more areas of the surface having a different composition and/or surface functional group. For example, the heterogeneous surface can comprise an elastomer surface, 548, and the surfaces, 542 and 543, of a coating layer, 545. The properties of surfaces 542 and 543 can be the same or different. In some embodiments, a boundary between different areas of the heterogeneous areas of the surface is defined by the lateral dimension of a protrusion.

In some embodiments, the heterogeneous stamp of the present invention further comprises a rigid or semi-rigid backing layer. In some embodiments, a rigid or semi-rigid backing layer is positioned opposite to a surface of the heterogeneous stamp composition.

The present invention is also directed to a method of preparing a heterogeneous elastomeric stamp composition, the method comprising:
(a) providing a master having a protrusion thereon having a minimum lateral dimension of about 100 μm or less;
(b) depositing onto the master an elastomeric precursor, wherein the elastomeric precursor covers the protrusion and the surface of the master surrounding the protrusion;
(c) curing the elastomeric precursor to form an elastomer;
(d) removing the elastomer from the master to provide an elastomeric stamp having an indentation therein, the indentation having a dimension defined by the protrusion; and
(e′) selectively depositing a coating layer onto either the surface of the elastomer or the surface of the indentation, wherein the coating layer has a surface energy different than the elastomer; or
(e″) filling at least a portion of the at least one indentation with a composition.

The heterogeneous stamp and stencil compositions can comprise a polymer, a polymer precursor, a metal, a metal oxide, an organometallic compound, a ceramic, and combinations thereof derivatized with a functional group such as, but not limited to, hydroxyl, alkoxyl, thiol, alkylthio, silyl, alkylsilyl, alkylsilenyl, siloxyl, primary amino, secondary amino, tertiary amino, carbonyl, alkylcarbonyl, aminocarbonyl, carbonylamino, carboxyl, phosphate, and combinations thereof, as defined above.

In some embodiments, the stamp and stencil compositions comprise a second elastomeric precursor having one or more functional groups, density, elasticity, and/or electromagnetic transparency that differs from the elastomeric precursor used to form the elastomer.

In some embodiments, the above process further comprises filling the at least one indentation such that the composition forms a smooth boundary with the surface of the elastomeric stamp. In some embodiments, filling the at least one indentation with a composition is followed by mechanical wiping (e.g., doctor blading, and the like), spin casting, or any other process known to those of ordinary skill in the art, to remove any excess composition from the indentation in and/or the surface of the elastomeric stamp.

In some embodiments, the above process further comprises curing the composition, for example, to spatially stabilize the composition (e.g., by cross-linking the composition, drying the composition, adhering the composition to the elastomeric stamp, and the like, and combinations thereof).

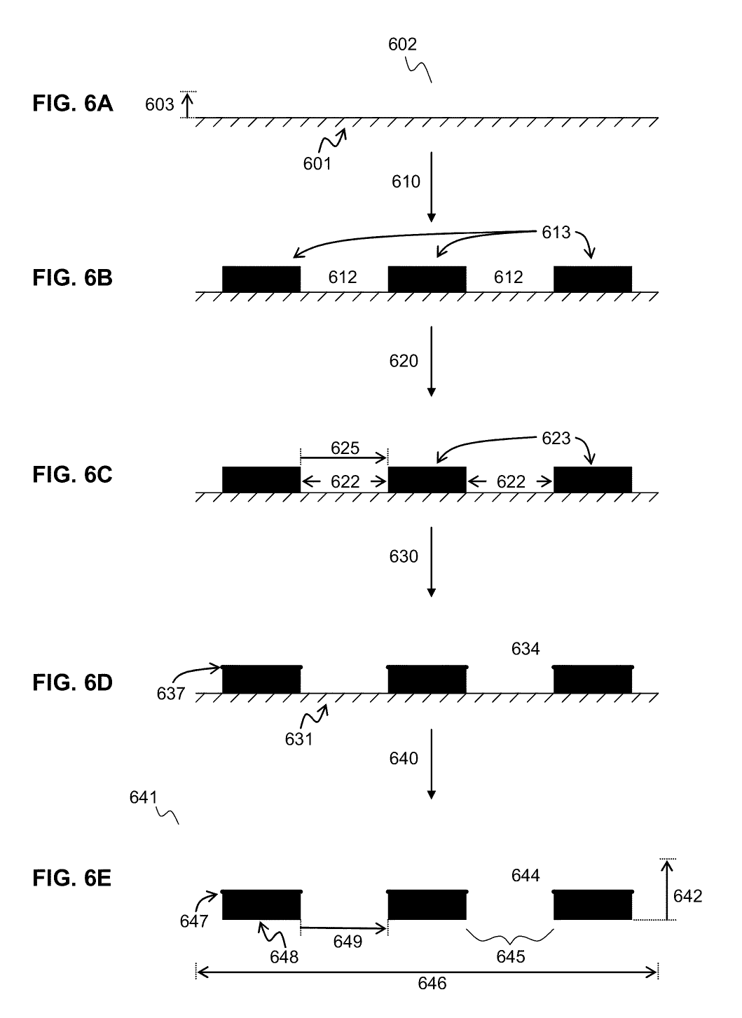

The present invention is also directed to methods for preparing a heterogeneous elastomeric stencil. FIGS. 6A-6E, 7A-7E, 8A-8E, 9A-9E and 10A-10D provide cross-sectional graphic representations of processes suitable for preparing heterogeneous stencils.

FIGS. 6A-6E provide a graphic representation of a method for preparing a stencil, the method comprising:
(a) coating a surface with a photoimageable elastomeric precursor;
(b) patterning the photoimageable elastomeric precursor to provide an elastomeric layer that includes a plurality of openings therein, the openings having at least one lateral dimension of about 100 μm or less;
(c) affixing a porous membrane to the elastomeric layer;
(d) separating the elastomeric layer from the surface, thereby providing the stencil, wherein the stencil has a front surface with a flatness of about 20% or less of the stencil thickness.

Referring to FIG. 6A, a photoimageable elastomeric precursor composition, 602, is coated onto a surface, 601, wherein the coating has a thickness 603.

The photoimageable elastomeric precursor is then patterned, 610, using photolithographic methods, followed by curing to provide a photoimaged elastomer. Referring to FIG. 6B, the patterning provides regions of cross-linked elastomer, 613, interspersed with regions wherein the photoimageable elastomeric precursor that is not cross-linked, 612. Developing, 620, of the photoimaged elastomeric composition provides a patterned elastomer. Referring to FIG. 6C, a pattern is provided that comprises an elastomeric layer, 623, that includes a plurality of openings therein, 622, the openings having at least one lateral dimension, 625, of about 100 μm or less.

A porous membrane is then affixed, 630, to the patterned elastomeric composition. Referring to FIG. 6D, the affixing comprises contacting a porous membrane, 634, with the patterned elastomeric layer, 633. In some embodiments, an additional layer, 637, is present between the porous membrane and the patterned elastomeric layer. Suitable components for use in an additional layer, 637, are described herein.

The patterned elastomeric layer is then separated, 640, from the surface, 631, to provide a stencil, 641. Referring to FIG. 6E, the stencil, 641, in some embodiments, has a flatness, 646, across the front surface, 648, that is about 20% or less of the stencil thickness, 642. The stencil comprises a porous membrane, 644, a front surface, 648, that includes a contact layer, 643, having a plurality of openings therein, 645, the openings having at least one lateral dimension, 649, of about 100 μm or less. An optional additional layer, 647, can be present between the contact layer and the porous membrane.

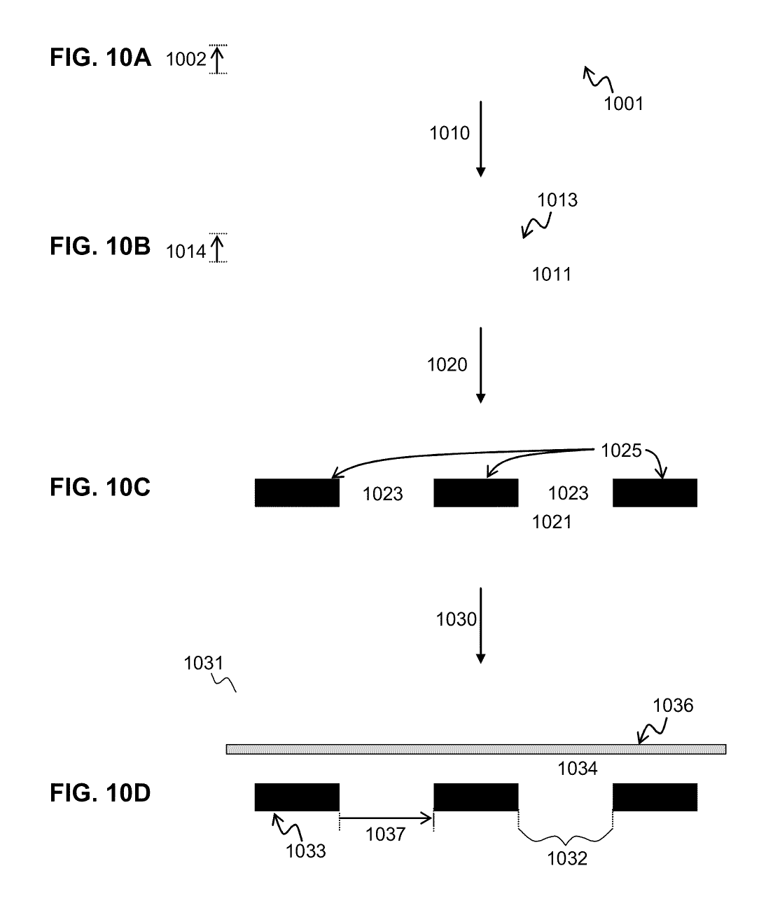

FIGS. 10A-10D provide a graphic representation of a method for preparing a stencil, the method comprising:
(a) coating a porous membrane with a photoimageable elastomeric precursor; and
(b) patterning the photoimageable elastomeric precursor to provide the stencil comprising a patterned elastomeric layer on the porous membrane, wherein the patterned elastomeric layer includes a plurality of openings therein, the openings having at least one lateral dimension of about 100 μm or less, and wherein the stencil has a front surface with a flatness of about 20% or less of the stencil thickness.

Referring to FIG. 10A, a porous membrane, 1001, is provided, the porous membrane having a thickness, 1002. In some embodiments, the porous membrane is rigid and has a Young's modulus of about 10 GPa or greater. A photoimageable elastomeric precursor composition is then coated, 1010, onto a surface of the porous membrane.

Referring to FIG. 10B, a photoimageable elastomeric precursor composition, 1013, has a thickness 1014.

The photoimageable elastomeric precursor is then patterned, 1020, using photolithographic methods, followed by curing to provide a photoimaged elastomer. Referring to FIG. 10C, the patterning provides regions of cross-linked elastomer, 1025, interspersed with regions wherein the photoimageable elastomeric precursor that is not cross-linked, 1023. Developing, 1030, of the photoimaged elastomeric composition provides a stencil. Referring to FIG. 10D, a stencil, 1031, is provided comprising a porous membrane, 1034, having an elastomeric layer, 1035, thereon, and having a front surface, 1033, that includes a plurality of openings therein, 1032, the openings having at least one lateral dimension, 1037, of about 100 μm or less. In some embodiments, a rigid member, 1036, can be further affixed to the porous membrane, 1034, for example, on any of a backside, an edge, or any other surface of the porous membrane. Not being bound by any particular theory, a rigid member can facilitate uniform contact between a front surface of a stencil and a substrate, and uniform patterning of a substrate.

In some embodiments, a method of the present invention comprises coating a photoimageable elastomeric precursor onto a surface, wherein the photoimageable elastomeric precursor includes: a photocurable monomer, an elastomeric binder, and a photoinitiator.

Photocurable monomers suitable for use with the present invention include, but are not limited to, a linear acrylate, a branched acrylate, a methacrylate, and combinations thereof.

In some embodiments, an elastomeric binder includes an accessible vinyl side-chain (e.g., a vinyl side-chain that is sterically accessible). Elastomeric binders suitable for use with the present invention include, but are not limited to, a styrene butadiene rubber, a styrene isoprene rubber, a polyurethane, and a polysiloxane.

Photoinitiators suitable for use with the present invention include, but are not limited to, Irgacure 907, Esacure TZT, Esacure SM308, and combinations thereof.

In some embodiments, a photoimageable elastomeric precursor includes a solvent. Solvents suitable for use in a photoimageable elastomeric precursor include, but are not limited to, aromatic solvents (e.g., toluene, xylene, and the like), esters, glycol-esters and/or glycol-ethers (e.g., ethyl acetate, propylene glycol methyl ether acetate, and the like), and combinations thereof.

Coating methods suitable for use with the present invention include, but are not limited to, spin-coating, dip-coating, spray-coating, and slit-coating.

In some embodiments, a photoimageable elastomeric precursor further comprises an additive selected from: a wetting agent, a stabilizer, an anti-oxidant, a photocuring accelerator, and combinations thereof. Stabilizers suitable for use with a photoimageable elastomeric precursor include, but are not limited to, 2,6-di-tert-butyl-4-methylphenol, 1,4,4-trimethyl-2,3-diazobicyclo(3.2.2)-non-2-ene-2,3-dioxide, and the like, and combinations thereof.

In some embodiments, the patterning of a photoimageable elastomeric precursor comprises:
(i) positioning a photomask proximate to the coating layer comprising a photoimageable elastomeric precursor;
(ii) exposing the photoimageable precursor through the photomask with UV radiation for about 0.1 seconds to about 100 seconds to provide a photoimaged coating layer;
(iii) developing the photoimaged coating layer to remove regions of the photoimaged coating layer and provide a patterned elastomeric layer; and
(iv) drying the surface of the patterned elastomeric layer.

As used herein, positioning a photomask proximate to the coating layer refers to placing a photomask in a position such that a pattern of light impinges upon the coating layer. As used herein, “proximate” refers to positioning a photomask in physical contact with a coating layer, positioning a photomask near to a coating layer, or positioning a photomask in a photolithography tool having one or more transmissive or reflective optical elements and/or one or more transmissive fluids between the photomask and the coating layer, and the like.

The exposing of the photoimageable precursor through the photomask with UV radiation is for a time and under conditions for the UV radiation to induce a photochemical reaction in the coating layer comprising a photoimageable precursor. In some embodiments, the exposing is for about 0.1 seconds to about 100 seconds, about 0.1 seconds to about 60 seconds, about 0.1 seconds to about 30 seconds, about 0.1 seconds to about 10 seconds, about 0.1 seconds to about 5 seconds, or about 0.1 seconds to about 1 second. Radiation suitable for conducting the exposing has a wavelength of about 10 nm to about 400 nm, about 200 nm to about 400 nm, about 250 nm to about 400 nm, about 350 nm to about 400 nm, about 18 nm, about 157 nm, about 193 nm, about 254 nm, about 365 nm, or a combination thereof.

The developing the photoimaged coating layer to remove regions of the photoimaged coating layer and provide a patterned elastomeric layer can be achieved by processes known to persons of ordinary skill in the art, and typically includes washing the photoimaged coating layer with one or more solvents. Solvent systems for use during the developing can include aromatic solvents, (e.g., toluene, xylene, and the like), water, alcohols (e.g., methanol, ethanol, propanol, and the like), ethers, esters, glycols, combinations thereof, as well as optional additives such as surfactants, stabilizers, solubilizers, and the like.

The drying the surface of the patterned elastomeric layer can be performed using standard drying methods such as, but not limited to, blow-drying, heating, evaporative drying, vacuum drying, drying using a hygroscopic material, and the like, and combinations thereof.

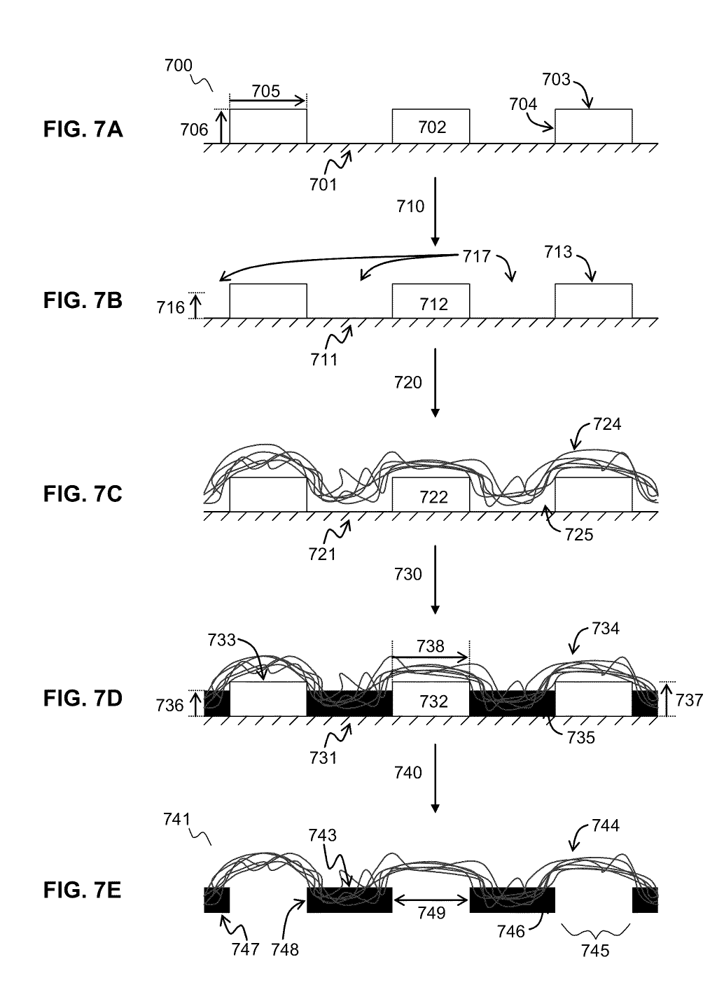

FIGS. 7A-7E provide a graphic representation of a method for preparing a stencil, the method comprising:
(a) providing a master having a protrusion thereon having a minimum lateral dimension of about 100 μm or less;
(b) providing an elastomeric precursor on the master having a thickness less than the elevation of the at least one protrusion;
(c) disposing onto the elastomeric precursor a flexible porous membrane;
(d) curing the elastomeric precursor to form an elastomer, wherein the porous membrane is bound to the elastomer; and
(e) separating the elastomer and master, thereby providing the heterogeneous elastomeric stencil, wherein the an elastomer has a front surface and a back surface including at least one opening there through, the opening defining a pattern in the surfaces of the elastomer and having a flexible porous membrane bound to the elastomer, wherein the opening has a lateral dimension defined by the protrusion, and wherein the elastomeric material has a thickness not greater than ten times the minimum lateral dimension.

Referring to FIG. 7A, a master, 700, including a surface, 701, having at least one protrusion, 702, thereon is provided. The at least one protrusion, 702, includes a top surface, 703, and a side surface, 704, having a lateral dimension, 705, and an elevation, 706, respectively, as defined above.

In some embodiments, the process comprises depositing an elastomeric precursor onto the master, 710.

Referring to FIG. 7B, an elastomeric precursor, 717, coating the surface of the master, 711, and having a thickness, 716, less than the height of a protrusion, 712, is provided. Thus, a surface of the protrusions, 713, projects from the elastomeric precursor composition, 717. The elastomeric precursor can be deposited by any of the methods described above, or any other deposition methods known to persons of ordinary skill in art.

In some embodiments, the process comprises disposing onto the elastomeric precursor a porous membrane to substantially cover the at least one protrusion. In some embodiments, a flexible porous membrane is bound to (e.g., adhered to or embedded in), the elastomeric precursor, 720. In some embodiments, a flexible porous membrane is applied to the elastomeric precursor such that upon curing, the flexible porous membrane is bound to the cured elastomer. For example, curing can physically entrap a flexible porous membrane in the elastomer, and/or adhere a flexible porous membrane to the elastomer (e.g., by a covalent bond, an ionic bond, a hydrogen bond, a static electric interaction, a magnetic interaction, or any combination thereof).

Referring to FIG. 7C, a composition comprising a flexible porous membrane, 724, bound to (e.g., adhered to or embedded in) an elastomeric precursor, 725, deposited on the surface of a master, 721, having a protrusion thereon, 722, is provided. In some embodiments, the flexible permeable material substantially covers the at least one protrusion. As used herein, “substantially covers” refers to spatial overlap of the flexible porous membrane with the at least one protrusion. Flexible porous membranes that substantially cover the at least one protrusion do not necessarily prevent the at least one protrusion from being viewed from above, reacting with a liquid, solid, vapor, gaseous, or plasma reagent, or being physically coated with an additional coating layer. In some embodiments, the structure and/or composition of the flexible porous membrane (e.g., a woven, filamentous, or porous structure) enables a protrusion to be “substantially covered” by a flexible porous membrane while enabling the protrusion to be viewed, accessed and/or reacted. In some embodiments, the flexible porous membrane can act as a reservoir for containing a reactive composition, for example, by a reactive composition wetting and/or swelling the flexible porous membrane, by a reactive composition being retained within pores present in the flexible porous membrane, by capillary action, adhesion, other another interaction between a reactive composition and the flexible porous membrane.

In some embodiments, the process comprises curing the elastomeric precursor to provide an elastomer, 730.

Referring to FIG. 7D, a heterogeneous stencil comprising an elastomer, 736, and a flexible porous membrane, 734, is provided. The heterogeneous stencil is formed over the surface of the master, 731, and around the at least one protrusion, 732. In some embodiments, curing comprises forming a covalent bond, a hydrogen bond, an ionic bond, or a combination thereof, between the contact layer, 736, and the flexible porous membrane, 734. For example, in some embodiments, a functional group on the continuous flexible porous membrane can react and/or interact with a group present in the elastomeric precursor and/or elastomer. In some embodiments, the flexible porous membrane is adhered to the elastomer, physically entrapped, or embedded in the elastomer by and/or during the curing process. The elastomer has a thickness, 736, that is less than the height of the at least one protrusion 737. Thus, the surface of the protrusion, 733, protrudes above the elastomer. The pattern in the front surface of the elastomeric stencil has a lateral dimension, 738, defined by the at least one protrusion, 732.

In some embodiments, the process comprises removing the heterogeneous elastomeric stencil from the surface of the master, 740.

Referring to FIG. 7E, the heterogeneous elastomeric stencil, 741, comprises an elastomer, 746, having front surface, 747, and a back surface, 743, having an opening there through, 745, the opening defining a pattern in the stencil. In some embodiments, the pattern in the stencil comprises two or more areas of the surface having a different composition and/or surface functional group. For example, a heterogeneous surface can comprise an elastomer surface on the front of the stencil, 747, and an inner surface of the opening, 748. The properties of surfaces 747 and 748 can be the same or different. In some embodiments, a boundary between different areas of the heterogeneous areas of the surface is defined by the lateral dimension of a protrusion.

In some embodiments, a flexible porous membrane is applied to a cured elastomer. The flexible porous membrane can be bound to an elastomer by an adhesive interaction (e.g., using a glue, epoxy), by pre-treating and/or chemically derivatizing the surface of the elastomer to and/or the surface of the flexible porous membrane to provide chemically reactive groups on either or both of the surface of the elastomer and/or the surface of the flexible porous membrane that are suitable for binding the surfaces to one another. In some embodiments, the flexible porous membrane can be applied to the surface of the elastomer and then a chemical, thermal, electromagnetic, and/or plasma treatment can be applied to bind the surfaces of the elastomer and the flexible porous membrane to one another.

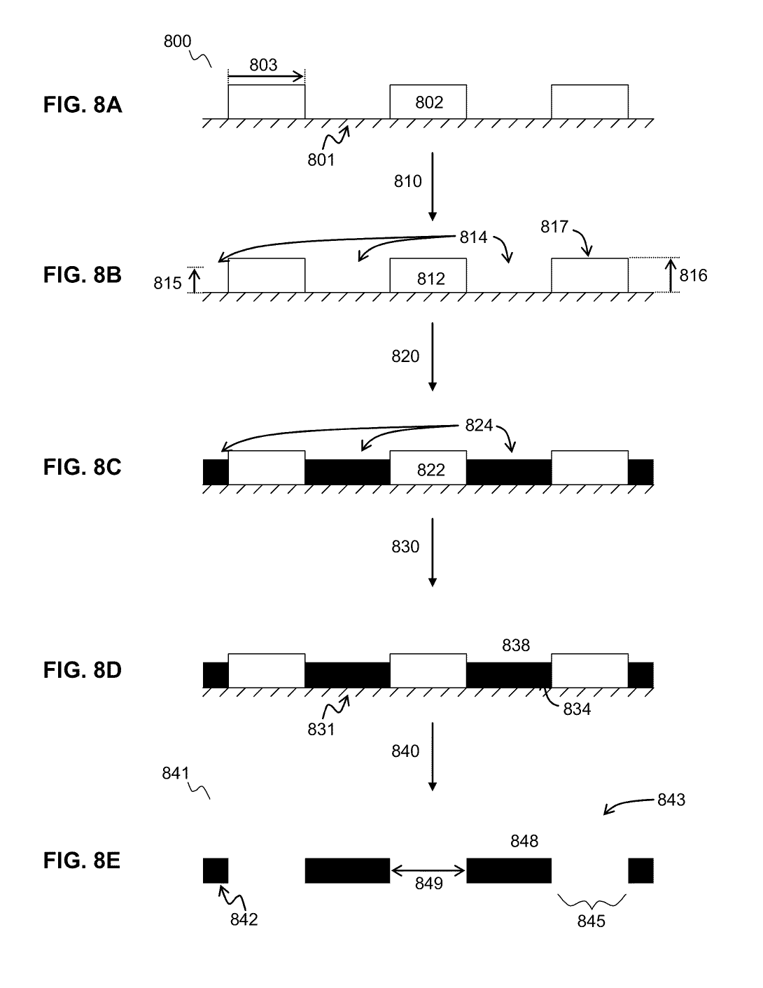

FIGS. 8A-8E provide a graphic representation of a method for preparing a stencil, the method comprising:
(a) providing a master having a protrusion thereon having at least one lateral dimension of about 100 μm or less;
(b) providing an elastomeric precursor on the master having a thickness less than the elevation of the at least one protrusion;
(c) curing the elastomeric precursor to form an elastomer;
(d) affixing onto the elastomer a porous membrane; and
(e) separating the elastomer and master, thereby providing the heterogeneous elastomeric stencil, wherein the an elastomer has a front surface and a back surface including at least one opening there through, the opening defining a pattern in the surfaces of the elastomer and having a porous membrane bound to the elastomer, wherein the opening has a lateral dimension defined by the protrusion, and wherein the elastomeric material has a thickness not greater than ten times the minimum lateral dimension.

Referring to FIG. 8A, a master, 800, having a surface, 801, that includes at least one protrusion thereon, 802, having at least one lateral dimension, 803, of about 100 μm or less is provided. An elastomeric precursor is then coated, 810, onto the master.

Referring to FIG. 8B, an elastomeric precursor coating, 814, has been applied to the master, wherein the elastomeric precursor coating has a thickness, 815, less than the height, 816, of a top surface, 817, of the protrusions, 812. The elastomeric precursor is then cured, 820.

Referring to FIG. 8C, curing of the elastomeric precursor provides an elastomer, 824, having a pattern therein defined by the protrusions, 822. A porous membrane is then affixed, 830, to the patterned elastomer.

Referring to FIG. 8D, a porous membrane, 838, is affixed to the elastomer, 834. The elastomer is then separated, 840, from the surface of the master, 831, to provide a stencil.

Referring to FIG. 8E, a stencil, 841, is provided having a front surface, 842, and a back surface, 843. The back surface includes a porous membrane, 848, and the front surface, 842, includes an elastomeric layer, 844, having a plurality of openings therein, 845, the openings having at least one lateral dimension, 849, of about 100 μm or less.

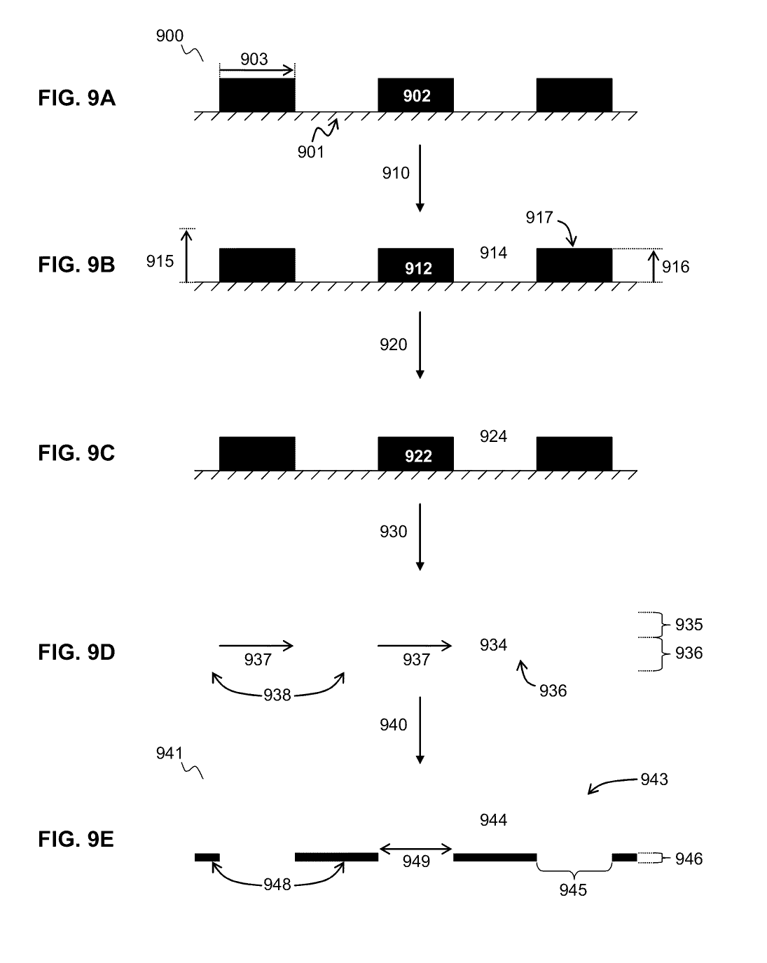

FIGS. 9A-9E provide a graphic representation of a method for preparing a stencil, the method comprising:
(a) providing a master having a protrusion thereon having at least one lateral dimension of about 100 μm or less;
(b) providing a porous membrane precursor on the master having a thickness greater than the elevation of the at least one protrusion;
(c) curing the porous membrane precursor to form a porous membrane;
(d) separating the porous membrane and master, thereby providing a porous membrane comprising a continuous portion having a plurality of protrusions extending therefrom; and
(e) affixing to at least an end portion of the plurality of protrusions an elastomer layer, thereby providing the heterogeneous stencil, wherein the elastomer layer include a plurality of openings therein defining a pattern in the elastomer layer and having a porous membrane bound to the elastomer layer, wherein the plurality of openings include at least one lateral dimension of about 100 μm or less, and wherein the elastomeric material has a thickness not greater than ten times a minimum lateral dimension.

Referring to FIG. 9A, a master, 900, having a surface, 901, that includes at least one protrusion thereon, 802, having at least one lateral dimension, 903, of about 100 μm or less is provided. A porous membrane precursor is then coated, 910, onto the master.

Referring to FIG. 9B, a porous membrane precursor, 914, has been applied to the master, wherein the porous membrane precursor coating has a thickness, 915, greater than the height, 916, of a top surface, 917, of the protrusions, 912. The porous membrane precursor is then cured, 920.

Referring to FIG. 9C, curing of the porous membrane precursor provides a porous membrane, 924, having a pattern therein defined by the protrusions, 922. The porous membrane is then separated from the master, 930.

Referring to FIG. 9D, a porous membrane, 934, is provided, the porous membrane having a continuous portion, 935, that includes a plurality of protrusions, 936, extending therefrom. The plurality of protrusions form a front surface, 938, of the porous membrane, and have a spacing, 937, defined by the lateral dimensions of the master.

An elastomer layer is then affixed, 940, to the front surface of the protrusions to provide a stencil.

Referring to FIG. 9E, a stencil, 941, is provided having a front surface, 948, and a back surface, 943. The back surface includes a porous membrane, 944, and the front surface, 948, includes an elastomeric layer, 946, having a plurality of openings therein, 945, the openings having at least one lateral dimension, 949, of about 100 μm or less.

In some embodiments, the conformally contacting occurs by applying pressure of about 10 kPa or less, about 8 kPa or less, about 5 kPa or less, or about 2 kPa or less to the stencil or the substrate. Not being bound by any particular theory, applying a pressure of about 10 kPa or less to the stencil or the substrate during the contacting can permit retention of the lateral dimensions of the plurality of openings during the patterning. In some embodiments, a combination of a stencil having a front surface with a flatness of about 20% or less of the stencil thickness and the presence of an elastomeric contact layer on a front surface of a stencil enables highly uniform patterns to be formed while applying a minimal pressure to the stencil (e.g., a pressure of about 10 kPa or less): the elastomeric layer ensures conformal contact is achieved between the stencil and the substrate, and the flatness of the stencil ensures uniform patterning across the surface of the stencil.

### Substrates

The present invention provides methods for forming a feature in or on a substrate. Substrates suitable for use with the present invention are not particularly limited by size, composition or geometry. For example, the nanobrushes of the present invention can be applied to planar, multi-planar or tiered, non-planar, flat, curved, spherical, rigid, flexible, symmetric, and asymmetric substrates, and any combination thereof. Nor are substrates suitable for use with the present invention limited by surface roughness or surface waviness, and the nanostructures can be equally applied to smooth, rough and wavy substrates, and substrates exhibiting heterogeneous surface morphology (i.e., substrates having varying degrees of smoothness, roughness and/or waviness).

As used herein, a substrate is “planar” if, after accounting for random variations in the height of a substrate (e.g., surface roughness, waviness, etc.), four points on the surface of the substrate lie in approximately the same plane. Planar substrates can include, but are not limited to, windows, embedded circuits, laminar sheets, solar panels, and the like.

As used herein, a substrate is “non-planar” if, after accounting for random variations in the height of a substrate (e.g., surface roughness, waviness, etc.), four or more points on the surface of the substrate do not lie in the same plane. Non-planar substrates can include, but are not limited to, building integrated photovoltaics, substrates comprising multiple different planar areas (i.e., “multi-planar” substrates), substrates having a tiered geometry, and combinations thereof. Non-planar substrates can comprise flat and/or curved areas.

As used herein, a substrate is “curved” when the radius of curvature of a substrate is non-zero over a distance of 100 μm or more, or 1 mm or more, across the surface of a substrate. A curved substrate can be patterned, for example, by a process in which a stencil having a flexible porous membrane is utilized and/or by a process in which a stencil having a rigid porous membrane with a shape that conforms to the three-dimensional shape of the substrate is utilized.

As used herein, a substrate is “rigid” when the plane, curvature, and/or geometry of a substrate cannot be easily distorted. Rigid substrates can undergo temperature-induced distortions due to thermal expansion, or become flexible at temperatures above a glass transition, melting point, and the like.

The plane, curvature, and/or geometry of a flexible substrate can be distorted flexed, and/or undergo elastic or plastic deformation, bending, compression, twisting, and the like in response to applied external force, stress, strain and/or torsion. Typically, a flexible substrate can be moved between flat and curved geometries. Flexible substrates suitable for use with the present invention include, but are not limited to, polymers (e.g., plastics), woven fibers, thin films, metal foils, composites thereof, laminates thereof, and combinations thereof. In some embodiments, a flexible substrate can be patterned using the methods of the present invention in a reel-to-reel manner.

Substrates for use with the present invention are not particularly limited by composition. Substrates suitable for use with the present invention include materials chosen from metals, crystalline materials (e.g., monocrystalline, polycrystalline, and partially crystalline materials), amorphous materials, conductors, semiconductors, insulators, optics, painted substrates, fibers, glasses, ceramics, zeolites, plastics, thermosetting and thermoplastic materials (e.g., optionally doped: polyacrylates, polycarbonates, polyurethanes, polystyrenes, cellulosic polymers, polyolefins, polyamides, polyimides, resins, polyesters, polyphenylenes, and the like), films, thin films, foils, plastics, polymers, wood, fibers, minerals, biomaterials, living tissue, bone, alloys thereof, composites thereof, laminates thereof, porous variants thereof, doped variants thereof, and combinations thereof.

In some embodiments, at least a portion of a substrate is transparent, translucent, or opaque to visible, UV, and/or infrared light). In some embodiments, a substrate is reflective to at least one wavelength of radiation in the UV and/or visible range. In some embodiments, a substrate for use with the present invention is substantially transparent or reflective in the wavelength range of about 350 nm to about 900 nm, or about 8 μm to about 13 μm.

In some embodiments, at least a portion of a substrate is conductive or semiconductive. As used herein, “conductive” and “semiconductive” materials include species, compounds, polymers, films, coatings, substrates, and the like capable of transporting or carrying electrical charge. Generally, the charge transport properties of a semiconductive material can be modified based upon an external stimulus such as, but not limited to, an electrical field, a magnetic field, a temperature change, a pressure change, exposure to radiation, and combinations thereof. In some embodiments, a conductive or semiconductive material has an electron or hole mobility of about 10⁻⁶ cm²V·s or more, about 10⁻⁵ cm²V·s or more, about 10⁻⁴ cm²V·s or more, about 10⁻³ cm²V·s or more, about 0.01 cm²V·s or more, or about 0.1 cm²V·s or more. Electrically conductive and semiconductive materials include, but are not limited to, metals, alloys, thin films, crystalline materials, amorphous materials, polymers, laminates, foils, plastics, and combinations thereof.

In some embodiments, a substrate comprises a semiconductor such as, but not limited to: crystalline silicon, polycrystalline silicon, amorphous silicon, p-doped silicon, n-doped silicon, silicon oxide, silicon germanium, germanium, gallium arsenide, gallium arsenide phosphide, indium tin oxide (ITO), laminates thereof, and combinations thereof.

In some embodiments, a substrate comprises a glass such as, but not limited to, undoped silica glass (SiO₂), fluorinated silica glass, borosilicate glass, borophosphorosilicate glass, organosilicate glass, porous organosilicate glass, and combinations thereof.

In some embodiments, a substrate comprises a ceramic such as, but not limited to, zinc sulfide (ZnSₓ), boron phosphide (BPₓ), gallium phosphide (GaPₓ), silicon carbide (SiCₓ), hydrogenated silicon carbide (H:SiCₓ), silicon nitride (SiNₓ), silicon carbonitride (SiCₓN_{y}), silicon oxynitride (SiOₓN_{y}), silicon oxycarbide (SiOₓC_{y}), silicon carbon-oxynitride (SiCₓO_{y}N_{z}), hydrogenated variants thereof, doped variants (e.g., n-doped and p-doped variants) thereof, and combinations thereof (where x, y, and z can vary independently from about 0.1 to about 5, about 0.1 to about 3, about 0.2 to about 2, or about 0.5 to about 1).

In some embodiments, the substrate comprises a flexible material, such as, but not limited to: a plastic, a composite, a laminate, a thin film, a metal foil, and combinations thereof.

In some embodiments, a substrate comprises a composite material having a conductive or semi-conductive layer over an insulator. For example, ITO on glass, a conductive metal on a plastic, and the like.

The surface area of a substrate is not particularly limited can be easily scaled by the proper design of equipment suitable for disposing the patterns of the present invention, and can range, without limitation, from about 1 mm² to about 20 m², or about 1 cm² to about 10 m².

Exemplary articles, objects and devices comprising the patterned substrates prepared a method of the present invention include, but are not limited to, solar cells; windows; mirrors; optical elements (e.g, optical elements for use in eyeglasses, cameras, binoculars, telescopes, and the like); lenses (e.g., fresnel lenses, etc.); watch crystals; optical fibers, output couplers, input couplers, microscope slides, holograms; cathode ray tube devices (e.g., computer and television screens); optical filters; data storage devices (e.g., compact discs, DVD discs, CD-ROM discs, and the like); flat panel electronic displays (e.g., LCDs, plasma displays, and the like); touch-screen displays (such as those of computer touch screens and personal data assistants); solar cells; flexible electronic displays (e.g., electronic paper and books); cellular phones; global positioning systems; calculators; graphic articles (e.g., signage); motor vehicles (e.g., wind screens, windows, displays, and the like); artwork (e.g., sculptures, paintings, lithographs, and the like); membrane switches; jewelry; and combinations thereof.

### Reactive Compositions

As used herein, a “reactive composition” refers to a composition suitable for reacting with a substrate. In some embodiments, the reactive composition includes more than one component and is a “heterogeneous reactive composition” having more than one excipient or component. As used herein, a “reactive composition” can refer to a liquid, a vapor, a gas, a plasma, a solid, a paste, an ink, a gel, a cream, a glue, an adhesive, a particulate, a suspension, a colloid, and combinations thereof. In some embodiments, a reactive composition for use with the present invention has a physical property, an electrical property, and combinations thereof that can be controlled by one or more external conditions such as temperature, pressure, electrical current, and the like.

In some embodiments, a reactive composition suitable for use with the present invention comprises a solvent and a thickening agent. In some embodiments, the combination of a solvent and a thickening agent can be selected to adjust the viscosity of a reactive composition. In some embodiments, a reactive composition for use with the present invention has a viscosity that can be adjusted from about 0.1 cP to about 10,000 cP.

Solvents suitable for use in a reactive composition of the present invention include, but are not limited to, organic solvents, inorganic solvents (e.g., water), solubilizing agents, molten metals, and combinations thereof.

Thickening agents suitable for use with a reactive composition of the present invention include, but are not limited to, metal salts of polymers having ionizable side groups, dendrimers, colloids, and combinations thereof.

In some embodiments, as the lateral dimensions of the desired surface features decrease it is necessary to reduce the particle size or physical length of components in a reactive composition. For example, for surface features having a lateral dimension of about 100 nm or less it can be necessary to reduce or eliminate polymeric components from a reactive composition.

In some embodiments, a reactive composition suitable for use with the present invention comprises an etchant. As used herein, an “etchant” refers to a component that can react with a substrate to remove a portion of the substrate. Thus, an etchant is used to form a subtractive feature, and in reacting with a substrate, forms at least one of a volatile material that can diffuse away from the substrate, or a residue, particulate, or fragment that can be removed from the substrate by, for example, a rinsing or cleaning process.

The composition and/or morphology of a substrate that can react with an etchant is not particularly limited. Subtractive features formed by reacting an etchant with a substrate are also not particularly limited so long as the material that reacts with the etchant can be removed from the resulting subtractive surface feature. Not being bound by any particular theory, an etchant can remove material from a substrate by reacting with the substrate to form a volatile product, a residue, a particulate, or a fragment that can, for example, be removed from the substrate by a rinsing or cleaning process. For example, in some embodiments an etchant can react with a metal or metal oxide substrate to form a volatile fluorinated metal species. In some embodiments, an etchant can react with a substrate to form an ionic species that is water soluble. Additional processes suitable for removing a residue or particulate formed by reaction of an etchant with a substrate are disclosed in U.S. Pat. No. 5,894,853, which is incorporated herein by reference in its entirety.

Etchants suitable for use with the present invention include, but are not limited to, an acidic etchant, a basic etchant, a fluoride-based etchant, and combinations thereof. Reactive compositions containing an etchant that are suitable for use with the present invention are disclosed in, for example, U.S. Pat. Nos. 5,688,366 and 6,388,187; and U.S. Patent Appl. Pub. Nos. 2003/0160026; 2004/0063326; 2004/0110393; and 2005/0247674, which are herein incorporated by reference in their entirety.

In some embodiments, a reactive composition further comprises a species that has a chemical interaction with a substrate. In some embodiments, a reactive composition penetrates or diffuses into the body of a substrate. In some embodiments, a reactive composition transforms, binds, or promotes binding to exposed functional groups on the surface of a substrate. Reactive compositions suitable for use with the present invention further include ions, free radicals, metals, acids, bases, metal salts, organic reagents, and combinations thereof.

In some embodiments, a reactive composition further comprises a conductor. As used herein, a “conductor” refers to a compound or species that can transfer or move electrical charge and also includes semiconductors and the like. Conductors suitable for use with the present invention include, but are not limited to, a metal, a nanoparticle, a polymer, a cream solder, a resin, and combinations thereof. Semiconductors suitable for use with the present invention include, but are not limited to, organic semiconductors, inorganic semiconductors, and combinations thereof.

Metals suitable for use with the present invention include, but are not limited to, a transition metal, aluminum, silicon, phosphorous, gallium, germanium, indium, tin, antimony, lead, bismuth, alloys thereof, and combinations thereof. In some embodiments, a metal is present as a nanoparticle (i.e., a particle having a diameter of 100 nm or less, or about 0.5 nm to about 100 nm). Nanoparticles suitable for use with the present invention can be homogeneous, multilayered, functionalized, and combinations thereof.

Organic semiconductors suitable for use with the present invention include, but are not limited to, arylene vinylene polymer, polyphenylenevinylene, polyacetylene, polythiophene, polyimidazole, tetracene, pentacene, hexacene, perylene, terylene, quaterylene, coronene, and combinations thereof.

Reactive compositions comprising conductors suitable for use with the present invention are further disclosed in U.S. Pat. Nos. 5,504,015; 5,296,043; and 6,703,295 and U.S. Patent Appl. Pub. No. 2005/0115604, which are incorporated herein by reference in their entirety.

In some embodiments, a reactive composition further comprises an insulator. As used herein, an “insulator” refers to a compound or species that is resistant to the movement or transfer of electrical charge. In some embodiments, an insulator has a dielectric constant of about 1.5 to about 8 about 1.7 to about 5, about 1.8 to about 4, about 1.9 to about 3, about 2 to about 2.7, about 2.1 to about 2.5, about 8 to about 90, about 15 to about 85, about 20 to about 80, about 25 to about 75, or about 30 to about 70. Insulators suitable for use with the present invention include, but are not limited to, a polymer, a polymer precursor, a metal oxide, a metal carbide, a metal nitride, monomeric precursors thereof, particles thereof, and combinations thereof. Suitable polymers include, but are not limited to, a polydimethylsiloxane, a silsesquioxane, a polyethylene, a polypropylene, and combinations thereof. In some embodiments, an insulator is present in a reactive composition in a concentration of about 1% to about 80% by weight of the reactive composition.

In some embodiments, a reactive composition further comprises a masking component. As used herein, a “masking component” refers to a compound or species that upon reacting forms a surface feature resistant to a species capable of reacting with the surrounding substrate. Masking components suitable for use with the present invention include materials commonly employed in traditional photolithography methods as “resists” (e.g., photoresists). Masking components suitable for use with the present invention include, but are not limited to, cross-linked aromatic and aliphatic polymers, non-conjugated aromatic polymers and copolymers, polyethers, polyesters, copolymers of C₁-C₈ alkyl methacrylates and acrylic acid, copolymers of paralyne, and combinations thereof. In some embodiments, a masking component is present in a reactive composition in a concentration of about 5% to about 98% by weight of the reactive composition.

In some embodiments, a reactive composition comprises a conductor and a reactive component. For example, a reactive component present in a reactive composition can promote at least one of: penetration of a conductor into a substrate, reaction between the conductor and a substrate, adhesion between a conductive feature and a substrate, promoting electrical contact between a conductive feature and a substrate, and combinations thereof. Surface features formed by this method include additive non-penetrating, additive penetrating, subtractive penetrating, and conformal penetrating surface features.

In some embodiments, a reactive composition comprises an etchant and a conductor, for example that can be used to produce a subtractive surface feature having a conductive feature inset therein.

In some embodiments, a reactive composition comprises an insulator and a reactive component. For example, a reactive component can promote at least one of: penetration of an insulator into a substrate, reaction between the insulator and a substrate, adhesion between an insulating feature and a substrate, promoting electrical contact between an insulating feature and a substrate, and combinations thereof. Surface features formed by the present method include: additive non-penetrating, additive penetrating, subtractive penetrating, and conformal penetrating surface features.

In some embodiments, a reactive composition comprises an etchant and an insulator, for example that can be used to produce a subtractive surface feature having an insulating feature inset therein.

In some embodiments, a reactive composition comprises a conductor and a masking component, for example, that can be used to produce an electrically conductive masking feature on a substrate.

### Applying and Reacting

The present invention is directed to a method for patterning a substrate, the method comprising:
(a) providing a heterogeneous stamp composition comprising: (i) a first surface comprising an elastomeric material including at least one indentation therein, the indentation defining a first pattern in the surface of the heterogeneous stamp composition, wherein the first pattern has a lateral dimension of about 100 μm or less, (ii) a second surface adjacent to the first surface and having a boundary there between, the boundary defining a second pattern in the surface of the heterogeneous stamp composition;
(b) applying a reactive composition to the heterogeneous stamp surface, wherein the reactive composition has a differential affinity for the first and second surfaces of the heterogeneous stamp composition;
(c) conformally contacting at least the first surface of the heterogeneous stamp composition with a substrate; and
(d) transferring the reactive composition from the heterogeneous stamp composition to the substrate in a third pattern that is defined by both the first and second patterns in the surfaces of the heterogeneous stamp composition.

The present invention is also directed to a method for forming a feature on a substrate, the method comprising:
(a) providing a stencil comprising an elastomeric material having a front surface and a back surface including an opening there through, the opening defining a pattern in the surfaces of the elastomeric material, wherein the opening has a minimum lateral dimension of about 100 μm or less; and a flexible, permeable material bound to at least a portion of the elastomeric material that provides a continuous layer on the back surface of the elastomeric material;
(b) conformally contacting the front surface of the stencil with a substrate;
(c) applying an reactive composition to the back surface of the stencil, wherein the reactive composition permeates the flexible, permeable material; and
(d) reacting the reactive composition with the substrate to produce a feature thereon, wherein the feature has a lateral dimension corresponding to lateral dimension of the opening in the stencil.

A reactive composition can be applied to a surface of a stamp or an opening in a stencil by methods known in the art such as, but not limited to, screen printing, ink jet printing, syringe deposition, spraying, spin coating, brushing, vapor depositing, plasma depositing, and exposing to a vapor source, light source, plasma source, and combinations thereof. Applying a reactive composition to a stamp or stencil can comprise rotating the stamp or stencil at about 100 revolutions per minute (rpm) to about 5,000 rpm, or about 1,000 rpm to about 3,000 rpm, while pouring or spraying the reactive composition onto the rotating stamp or stencil.

In some embodiments, a reactive composition is poured onto the back surface of a stencil, and then a blade is moved transversely across the surface of the stencil to ensure that the openings in the stencil are completely and uniformly filled. The blade can also remove excess of the reactive composition from the surface of the stamp.

Applying a reactive composition to a stamp or stencil completely and uniformly covers the surface of the stamp, fills an at least one indentation in the surface of the stamp, or fills an opening through the surfaces of a stencil. Not being bound by any particular theory, as the lateral dimensions of the opening in the stamp or stencil become smaller, the viscosity of the reactive composition can be decreased and/or the thickness of the stencil can be decreased to ensure that the pattern in the stamp or stencil is filled and/or uniformly covered by a reactive composition. Non-uniform application of the reactive composition to a stamp or stencil can result in a failure to correctly and reproducibly produce surface features having the desired lateral dimensions.

In some embodiments, a reactive composition can be formulated to control its viscosity. In some embodiments, the viscosity of a reactive composition is modified during one or more of an applying step, contacting step, reacting step, and combinations thereof.

Transfer of the reactive composition from a stamp or through a stencil to a substrate can be promoted by an interaction between the reactive composition and the surface of the stamp or stencil, an interaction between the reactive composition and the substrate, an interaction between the surface of the stamp or stencil and the substrate, and combinations thereof, that promote adhesion of a reactive composition to the substrate. Not being bound by any particular theory, adhesion of a reactive composition to the substrate can be promoted by gravity, a Van der Waals interaction, a covalent bond, an ionic interaction, a hydrogen bond, a hydrophilic interaction, a hydrophobic interaction, a magnetic interaction, and combinations thereof. Conversely, the minimization of these interactions between a reactive composition and the surface of a stamp can facilitate transfer of the reactive composition from a stamp or through a stencil to a substrate.

In some embodiments, contacting the stamp or stencil with a substrate can be facilitated by applying pressure, vacuum, radiative heat, convective heat, or combinations thereof to the backside of either or all of the stamp, stencil, and substrate. In some embodiments, applying pressure, vacuum, radiative heat, convective heat, or combinations thereof can ensure that the reactive composition is substantially removed from between the surfaces of the stamp or stencil and the substrate. In some embodiments, applying pressure, vacuum, radiative heat, convective heat, or combinations thereof can ensure that there is conformal contact between the surfaces of the stamp or stencil and the substrate. In some embodiments, applying pressure, vacuum, radiative heat, convective heat, or combinations thereof can minimize the presence of gas bubbles present between the surfaces of the stamp or stencil and the substrate, or gas bubbles present in the reactive composition. Not being bound by any particular theory, the removal of gas bubbles can facilitate in the reproducible formation of surface features having lateral dimensions of 50 μm or less.

In some embodiments, the substrate, or the surface of a stamp or stencil, can be selectively patterned, functionalized, derivatized, textured, or otherwise pre-treated. As used herein, “pre-treating” refers to chemically or physically modifying a surface prior to applying or reacting a reactive composition. Pre-treating can include, but is not limited to, cleaning, oxidizing, reducing, derivatizing, functionalizing, exposing a substrate to a reactive gas, plasma, thermal energy, ultraviolet radiation, and combinations thereof. In some embodiments, pre-treating a substrate can increase or decrease an adhesive interaction between a reactive composition and the substrate, and facilitate the formation of surface features having a lateral dimension of about 50 μm or less.

In some embodiments, pre-treating a porous membrane can increase or decrease the permeability of a reactive composition through the porous membrane. In some embodiments, pre-treatment of a porous membrane includes (in addition to the pre-treating processes listed above): exposing to a corona discharge, exposing to ozone, and/or exposing to a solvent such as, but not limited to, water, isopropanol, toluene, and the like.

For example, derivatizing a substrate with a polar functional group (e.g., oxidizing the substrate) can promote the wetting of the substrate by a hydrophilic reactive composition and deter surface wetting by a hydrophobic reactive composition. Moreover, hydrophobic and/or hydrophilic interactions can be used to prevent a reactive composition from penetrating into the body of a stamp. For example, derivatizing the surface of a stamp with a fluorocarbon functional group can facilitate the transfer of a reactive composition from the opening in the stamp to the substrate without swelling of the stamp.

The method of the present invention produces surface features by reacting a reactive composition with a substrate. As used herein, “reacting” is used interchangeably with the term “reacts,” and both refer to a chemical reaction comprising at least one of: one or more components present in the reactive composition reacting with each other, one or more components of a reactive composition reacting with a substrate, one or more components of a reactive composition reacting with sub-surface region of a substrate, and combinations thereof.

In some embodiments, a reactive composition reacts upon contacting a substrate (i.e., a reaction is initiated upon contact between a reactive composition and a substrate). In some embodiments, a reaction is initiated by applying an external force to: a reactive composition, a substrate having a reactive composition proximate thereto, and combinations thereof.

In some embodiments, a reactive composition reacts via a chemical reaction between a reactive composition and a functional group on the substrate, or a chemical reaction between a reactive composition and a functional group below the surface of the substrate. Thus, methods of the present invention comprise reacting a reactive composition not only with a substrate, but also with a substrate below its surface, thereby forming inset or inlaid features on a substrate. Not being bound by any particular theory, a component of a reactive composition can react with a substrate by reacting on the surface of the substrate, or penetrating and/or diffusing into the substrate. In some embodiments, the penetration of a reactive composition into a substrate can be facilitated by applying pressure, vacuum, radiative heat, convective heat, or combinations thereof to the backside of a stamp or the substrate.

Reaction between a reactive composition and a substrate can modify one or more properties of the substrate, wherein the change in properties is localized to the portion of the substrate that reacts with the reactive composition. For example, a reactive metal particle can penetrate a substrate, and upon reacting, modify the conductivity of the substrate in the area and/or volume where the reacting occurs. In some embodiments, a reactive composition can penetrate the surface of a substrate and react selectively to increase the porosity of the substrate in the volume wherein the reacting occurs. In some embodiments, a reactive composition can selectively react with a crystalline material to increase or decrease its volume, or change the interstitial spacing of a crystalline lattice.

In some embodiments, reacting a reactive composition comprises chemically reacting a functional group on a substrate with a component of the reactive composition. Not being bound by any particular theory, a reactive composition can also react with only the surface of a substrate (i.e., no penetration and reaction with the substrate occurs below the surface). In some embodiments, a patterning method wherein only the surface of a substrate is changed can be useful for subsequent self-aligned deposition reactions.

In some embodiments, reacting the reactive composition with a substrate can comprise reactions that propagate into the plane of the substrate, as well as reactions in the lateral plane of the substrate. For example, a reaction between an etchant and a substrate can comprise the etchant penetrating into the surface of the substrate in the vertical direction (i.e., orthogonal to the surface of the substrate), such that the lateral dimensions of the lowest point of the surface feature are approximately equal to the dimensions of the feature at the plane of the substrate.

In some embodiments, etching reactions also occur laterally between a reactive composition and a substrate, such that the lateral dimensions at the bottom of a surface feature are more narrow than the lateral dimensions of the feature at the plane of the substrate. As used herein, “undercut” refers to situations when the lateral dimensions of a surface feature are greater than the lateral dimensions of an opening in a stamp used to apply a reactive composition to the substrate. Typically, undercut is caused by reaction of a reactive composition with a substrate in a lateral dimension, and can lead to the formation of beveled edges on subtractive features.

In some embodiments, the time of reaction can be selected to enable the formation of subtractive surface features having minimum undercut, and lateral dimensions identical to the lateral dimensions of a stamp or elastomeric stamp used to apply the reactive composition to the substrate.

In some embodiments, the reactive compositions for use with the present invention are formulated to minimize the reaction in a lateral dimension of a substrate (i.e., to minimize undercut). For example, a reactive composition can be applied to a substrate that is transparent to UV light, wherein illumination of the reactive composition through the backside of the substrate initiates a reaction between the reactive composition and the substrate. In some embodiments, the reaction initiator can activate a reactive composition through the backside of a stamp.

In some embodiments, reacting a reactive composition comprises removing solvent from the reactive composition. Not being bound by any particular theory, the removal of solvent from a reactive composition can solidify the reactive composition, or induce cross-linking reactions between components of a reactive composition. In some embodiments, a solvent can be removed from a reactive composition without heating. Solvent removal can also be achieved by heating the substrate, reactive composition, stamp, and combinations thereof. Cross-linking reactions can be intramolecular or intermolecular, and can also occur between a component and the surface of the substrate.

In some embodiments, reacting the reactive composition comprises sintering metal particles present in the reactive composition. Not being bound by any particular theory, sintering is a process in which metal particles join to form a continuous structure within a surface feature without melting. Sintering can be used to form both homogeneous and heterogeneous metal surface features.

In some embodiments, reacting comprises exposing a substrate, a reactive composition, or a combination thereof to a reaction initiator. Reaction initiators suitable for use with the present invention include, but are not limited to, thermal energy, electromagnetic radiation, acoustic waves, an oxidizing or reducing plasma, an electron beam, a stoichiometric chemical reagent, a catalytic chemical reagent, an oxidizing or reducing reactive gas, an acid or a base (e.g., a decrease or increase in pH), an increase or decrease in pressure, an alternating or direct electrical current, agitation, sonication, friction, and combinations thereof. In some embodiments, reacting comprises exposing a reactive composition to multiple reaction initiators.

Electromagnetic radiation suitable for use as a reaction initiator can include, but is not limited to, microwave light, infrared light, visible light, ultraviolet light, x-rays, radiofrequency, and combinations thereof.

In some embodiments, a stamp or stencil is removed before reacting the reactive composition. In some embodiments, the stamp is removed after reacting the reactive composition. Not being bound by any particular theory, leaving the stamp in place during the reacting step can ensure reproducible surface features are formed with the desired lateral dimensions. For example, removing the stamp after the reacting can ensure the reactive composition does not spread across the substrate prior to or during the reacting.

In some embodiments, the method of the present invention further comprises: exposing an area of a substrate adjacent to a surface feature to a reactive composition that reacts with the adjacent surface area, but which is unreactive towards the surface feature. For example, after producing a surface feature comprising a masking component, the remaining substrate can be exposed to an etchant, such as a gaseous etchant, a liquid etchant, and combinations thereof.

In some embodiments, prior to conformally contacting an elastomeric stamp or stencil with a substrate, the substrate is patterned by a micro-contact printing method. For example, a reactive composition is applied to an elastomeric stamp having at least one indentation in the surface of the elastomeric stamp which defines a pattern, to form a coated elastomeric stamp, and the coated stamp is placed in conformal contact with the substrate. The reactive composition is transferred from the surface of the coated elastomeric stamp that is in conformal contact with the substrate. The reactive composition adheres to the substrate, and can form at least one of a thin film, a monolayer, a bilayer, a self-assembled monolayer, and combinations thereof. In some embodiments the reactive composition can react with the substrate. A reactive composition can then be applied to the substrate in a pattern determined by an elastomeric stamp or stencil, wherein the reactive composition is reactive towards either one of the exposed substrate or the substrate coated by the reactive composition. The resulting patterned substrate includes a pattern having lateral dimensions determined by the pattern in the elastomeric stamp used to apply the reactive composition to the substrate as well as the pattern of the elastomeric stamp.

### Surface Features

The present invention provides methods for forming a feature in or on a substrate. As used herein, a “surface feature” refers to an area of a substrate that is contiguous with, and can be distinguished from, the areas of the substrate surrounding the feature. For example, a surface feature can be distinguished from the areas of the substrate surrounding the feature based upon the topography of the surface feature, composition of the surface feature, or another property of the surface feature that differs from the surrounding substrate.

Surface features can be defined by their physical dimensions. All surface features have a lateral dimension. As used herein, a “lateral dimension” refers to a dimension of a surface feature that lies in the plane of a substrate. One or more lateral dimensions of a surface feature define, or can be used to define, the area of a surface that a surface feature occupies. Typical lateral dimensions of surface features include, but are not limited to: length, width, radius, diameter, and combinations thereof.

All surface features also have at least one dimension that can be described by a vector that lies out of the plane of the substrate. As used herein, “elevation” refers to the largest vertical distance between the plane of a substrate and the highest or lowest point on a surface feature. More generally, the elevation of an additive surface feature refers to its highest point relative to the plane of the substrate, the elevation of a subtractive surface feature refers to its lowest point relative to the plane of the substrate, and a conformal surface feature has an elevation of zero (i.e., is at the same height as the plane of the substrate).

Surface features produced by the methods of the present invention can generally be classified into three groups: additive features, conformal features, and subtractive features, based upon the elevation of the surface feature relative to the plane of the substrate.

Surface features produced by the methods of the present invention can be further classified into two-subgroups: penetrating and non-penetrating, based upon whether or not the base of a surface feature penetrates below the plane of the substrate. As used herein, the “penetration distance” refers to the distance between the lowest point of a surface feature and the height of the substrate adjacent to the surface feature. More generally, the penetration distance of a surface feature refers to its lowest point relative to the plane of the substrate. Thus, a feature is said to be “penetrating” when its lowest point is located below the plane of the substrate on which the feature is located, and a feature is said to be “non-penetrating” when the lowest point of the feature is located within or above the plane of the substrate. A non-penetrating surface feature can be said to have a penetration distance of zero.

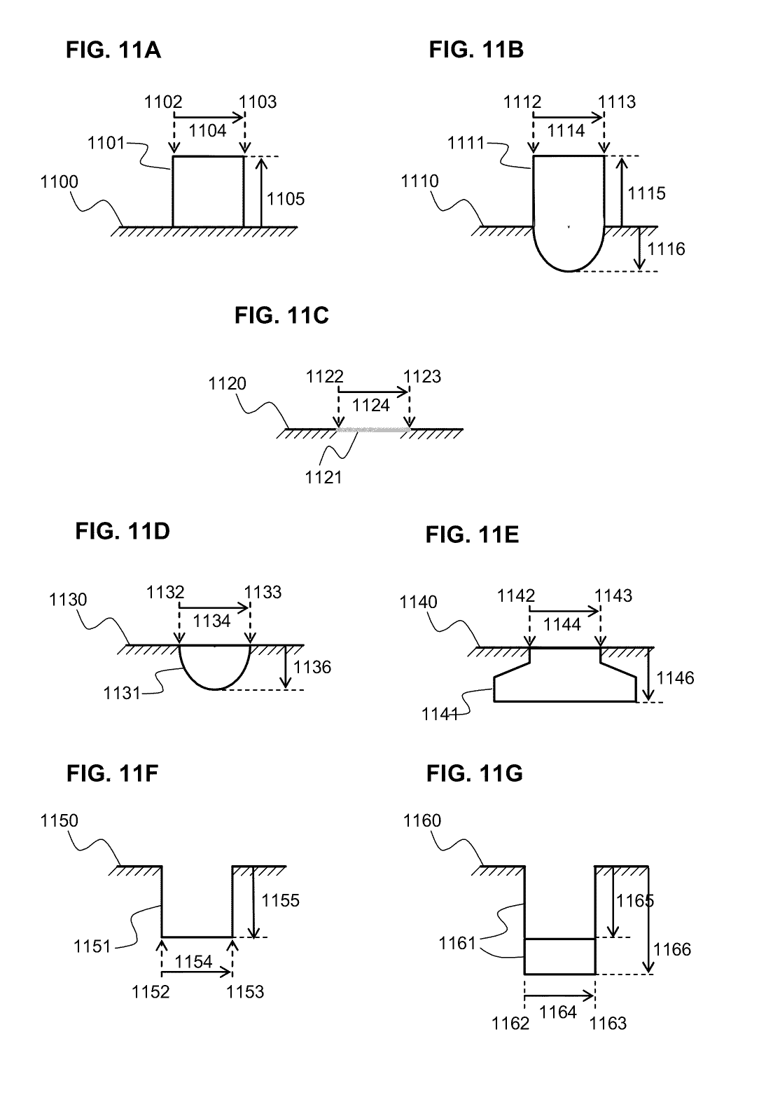

As used herein, an “additive feature” refers to a surface feature having an elevation that is above the plane of the substrate. Thus, the elevation of an additive feature is greater than the elevation of the surrounding substrate. FIG. 11A shows a cross-sectional schematic representation of a substrate, 1100, having an “additive non-penetrating” surface feature, 1101. The surface feature, 1101, has a lateral dimension, 1104, an elevation, 1105, and a penetration distance of zero. FIG. 11B shows a cross-sectional schematic representation of a substrate, 1110, having an “additive penetrating” surface feature, 1111. The surface feature, 1111, has a lateral dimension, 1114, an elevation, 1115, and a penetration distance, 1116.

As used herein, a “conformal feature” refers to a surface feature having an elevation that is even with the plane of the substrate. Thus, a conformal feature has substantially the same topography as the surrounding substrate. As used herein, a “conformal non-penetrating” surface feature refers to a surface feature that is purely on the substrate. For example, a reactive composition that reacts with the exposed functional groups of a substrate such as, for example, by oxidizing, reducing, or functionalizing the groups, would form a conformal non-penetrating surface feature. FIG. 11C shows a cross-sectional schematic representation of a substrate, 1120, having a “conformal non-penetrating” surface feature, 1121. The surface feature, 1121, has a lateral dimension, 1124, and has an elevation of zero and a penetration distance of zero. FIG. 11D shows a cross-sectional schematic representation of a substrate, 1130, having a “conformal penetrating” surface feature, 1131. The surface feature, 1131, has a lateral dimension, 1134, an elevation of zero, and penetration distance, 1136. FIG. 11E shows a cross-sectional schematic representation of a substrate, 1140, having a “conformal penetrating” surface feature, 1141. The surface feature, 1141, has a lateral dimension, 1144, an elevation of zero, and penetration distance, 1146.

As used herein, a “subtractive feature” refers to a surface feature having an elevation that is below the plane of the substrate. FIG. 11F shows a cross-sectional schematic representation of a substrate, 1150, having a “subtractive non-penetrating” surface feature, 1151. The surface feature, 1151, has a lateral dimension, 1154, an elevation, 1155, and penetration distance of zero. FIG. 11G shows a cross-sectional schematic representation of a substrate, 1160, having a “subtractive penetrating” surface feature, 1161. The surface feature, 1161, has a lateral dimension, 1164, an elevation, 1165, and a penetration distance, 1166.

Surface features can be further differentiated based upon their composition and utility. For example, surface features produced by a method of the present invention include structural surface features, conductive surface features, semi-conductive surface features, insulating surface features, and masking surface features.

As used herein, a “structural feature” refers to surface feature having a composition similar or identical to the composition of the substrate on which the surface feature is produced.

As used herein, a “conductive feature” refers to a surface feature having a composition that is electrically conductive, or electrically semi-conductive. Electrically semi-conductive features include surface features whose electrical conductivity can be modified based upon an external stimulus such as, but not limited to, an electrical field, a magnetic field, a temperature change, a pressure change, exposure to radiation, and combinations thereof.

As used herein, an “insulating feature” refers to a surface feature having a composition that is electrically insulating.

As used herein, a “masking feature” refers to a surface feature that has composition that is inert to reaction with a reagent that is reactive towards an area of a substrate adjacent to and surrounding the surface feature. Thus, a masking feature can be used to protect a substrate or a selected area of a substrate during subsequent process steps, such as, but not limited to, etching, deposition, implantation, and surface treatment steps. In some embodiments, a masking feature is removed during or after subsequent process steps.

### Feature Size and Measurement

A surface feature produced by a method of the present invention has lateral and vertical dimensions that are typically defined in units of length, such as angstroms (Å), nanometers (nm), microns (μm), millimeters (mm), centimeters (cm), etc.

When the substrate is planar, a lateral dimension of a surface feature is the magnitude of a vector between two points located on opposite sides of a surface feature, wherein the two points are in the plane of the substrate, and wherein the vector is parallel to the plane of the substrate. In some embodiments, two points used to determine a lateral dimension of a symmetric surface also lie on a mirror plane of the symmetric feature. In some embodiments, a lateral dimension of an asymmetric surface feature can be determined by aligning the vector orthogonally to at least one edge of the surface feature.

For example, in FIG. 11A-11G points lying in the plane of the substrate and on opposite sides of the surface features, 1101, 1111, 1121, 1131, 1141, 1151 and 1161, are shown by dashed arrows, 1102 and 1103; 1112 and 1113; 1122 and 1123; 1132 and 1133; 1142 and 1143; 1152 and 1153, and 1162 and 1163, respectively. The lateral dimension of these surface features is shown by the magnitude of the vectors 1104, 1114, 1124, 1134, 1144, 1154 and 1164, respectively.

A substrate is “curved” when the substrate has a radius of curvature that is non-zero over a distance of 100 μm or more, or over a distance of 1 mm or more. For a curved substrate, a lateral dimension is defined as the magnitude of a segment of the circumference of a circle connecting two points on opposite sides of the surface feature, wherein the circle has a radius equal to the radius of curvature of the substrate. A lateral dimension of a curved substrate having multiple or undulating curvature, or waviness, can be determined by summing the magnitude of segments from multiple circles.

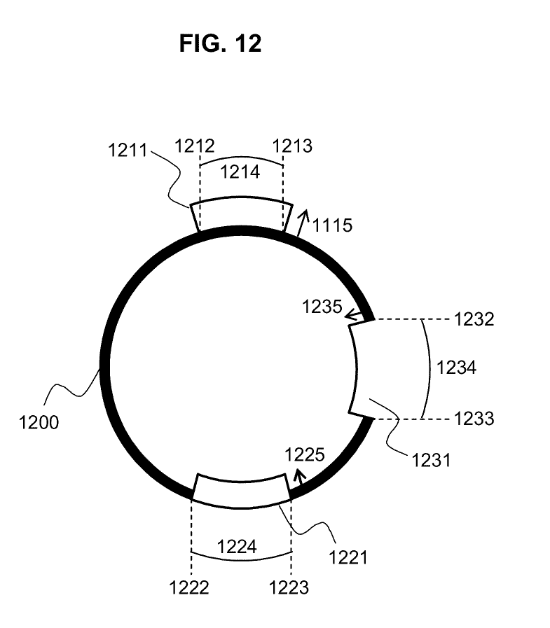

FIG. 12 provides a cross-sectional schematic representation of a curved substrate, 1200, having an additive non-penetrating surface feature, 1211, a conformal penetrating surface feature, 1221, and a subtractive non-penetrating surface feature, 1231. The additive non-penetrating surface feature, 1211, has a lateral dimension equivalent to the length of the line segment, 1214, which connects points 1212 and 1213, a penetration distance of zero, and an elevation equivalent to the magnitude of vector 1215. The conformal penetrating surface feature, 1221, has a lateral dimension equivalent to the length of the line segment, 1224, which connects points 1222 and 1223, a penetration distance equivalent to the magnitude of vector 1225, and an elevation of zero. The subtractive non-penetrating surface feature, 1231, has a lateral dimension equivalent to the length of the line segment, 1234, which connects points 1232 and 1233, a penetration distance of zero, and an elevation equivalent to the magnitude of vector 1235.

In some embodiments, a surface feature produced by a method of the present invention has a minimum lateral dimension not less than about 40 nm, about 50 nm, about 80 nm, about 100 nm, about 150 nm, about 200 nm, about 300 nm, about 400 nm, about 500 nm, about 600 nm, about 700 nm, about 800 nm, about 900 nm, about 1 μm, about 1.5 μm, about 2 μm, about 3 μm, about 5 μm, about 7 μm, about 10 μm, about 15 μm, about 20 μm, about 25 μm, about 30 μm, or about 35 μm. In some embodiments, a surface feature produced by a method of the present invention has a minimum lateral dimension not greater than about to about 100 μm, about 90 μm, about 80 μm, about 70 μm, about 60 μm, about 50 μm, or about 40 μm.

In some embodiments, a feature produced by a method of the present invention has an elevation or penetration distance of about 3 Å to about 100 μm, about 3 Å to about 50 μm, about 3 Å to about 10 μm, about 3 Å to about 1 μm, about 3 Å to about 500 nm, about 3 Å to about 100 nm, about 3 Å to about 50 nm, about 3 Å to about 10 nm, about 3 Å to about 1 nm, about 1 nm to about 100 μm, about 1 nm to about 50 μm, about 1 nm to about 10 μm, about 1 nm to about 1 μm, about 1 nm to about 500 nm, about 1 nm to about 100 nm, about 1 nm to about 50 nm, about 1 nm to about 10 nm, about 10 nm to about 100 μm, about 10 nm to about 50 μm, about 10 nm to about 10 μm, about 10 nm to about 1 μm, about 10 nm to about 500 nm, about 10 nm to about 100 nm, about 10 nm to about 50 nm, about 50 nm to about 100 μm, about 50 nm to about 50 μm, about 50 nm to about 10 μm, about 50 nm to about 1 μm, about 50 nm to about 500 nm, about 50 nm to about 100 nm, about 100 nm to about 100 μm, about 100 nm to about 50 μm, about 100 nm to about 10 μm, about 100 nm to about 1 μm, or about 100 nm to about 500 nm above or below the plane of a substrate.

In some embodiments, a surface feature produced by a method of the present invention has an aspect ratio (i.e., a ratio of either one or both of the elevation and/or penetration distance to a lateral dimension) of about 10:1 to about 1:10, about 8:1 to about 1:8, about 5:1 to about 1:5, about 2:1 to about 1:2, or about 1:1.

A lateral and/or vertical dimension of an additive or subtractive surface feature can be determined using an analytical method that can measure substrate topography such as, for example, scanning mode atomic force microscopy (AFM) or profilometry. Conformal surface features cannot typically be detected by profilometry methods. However, if the surface of a conformal surface feature is terminated with a functional group whose polarity differs from that of the surrounding surface areas, a lateral dimension of the surface feature can be determined using, for example, tapping mode AFM, functionalized AFM, or scanning probe microscopy.

Surface features can also be identified based upon a property such as, but not limited to, conductivity, resistivity, density, permeability, porosity, hardness, and combinations thereof using, for example, scanning probe microscopy.

In some embodiments, a surface feature can be differentiated from the substrate, for example, scanning electron microscopy or transmission electron microscopy.

In preferable embodiments of the present invention a surface feature has a different composition or morphology compared to the surrounding substrate. Thus, surface analytical methods can be employed to determine both the composition of the surface feature, as well as the lateral dimension of the surface feature. Analytical methods suitable for determining the composition and lateral and vertical dimensions of a surface feature include, but are not limited to, Auger electron spectroscopy, energy dispersive x-ray spectroscopy, micro-Fourier transform infrared spectroscopy, particle induced x-ray emission, Raman spectroscopy, x-ray diffraction, x-ray fluorescence, laser ablation inductively coupled plasma mass spectrometry, Rutherford backscattering spectrometry/Hydrogen forward scattering, secondary ion mass spectrometry, time-of-flight secondary ion mass spectrometry, x-ray photoelectron spectroscopy, and combinations thereof.

### EXAMPLES

### Example 1

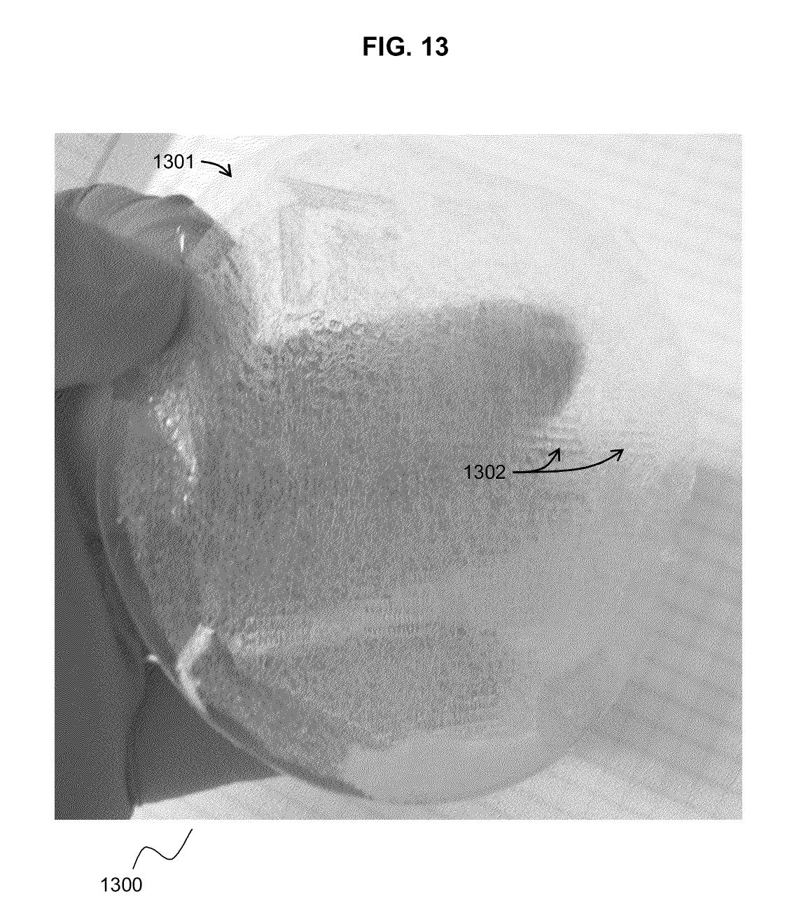

A heterogeneous stencil of the present invention was prepared as follows. A 75 mm silicon wafer was coated with a photoresist that was patterned using known processes to provide a master. Poly(dimethylsiloxane) was deposited onto the master to a thickness less than the height of the photoresist pattern. Woven poly(para-phenyleneterephthalamide) (KEVLAR®) was applied to the backside of the poly(dimethylsiloxane). The resulting composite structure was then cured at 80° C. for 1-2 hours. The resulting heterogeneous stencil composition comprising an elastomer having bound thereto a flexible, permeable material (i.e., poly(para-phenyleneterephthalamide)) was peeled from the master. FIG. 13 provides a photographic image, 1300, of the heterogeneous stencil, 1302. The stencil comprises a pattern, 1303.

### Example 2

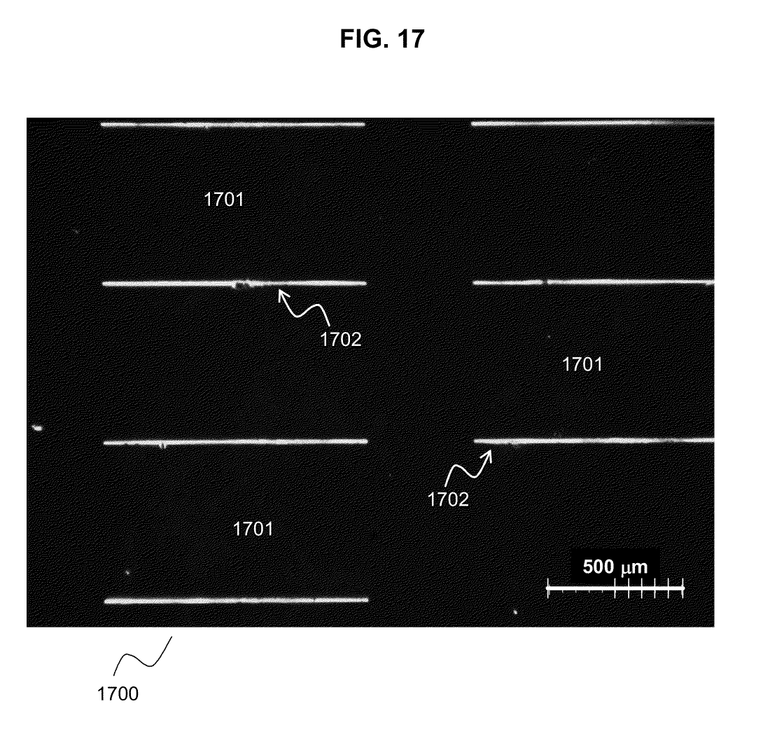

A substrate was patterned utilizing a heterogeneous stencil, as prepared in Example 1. A substrate, gold-coated poly(ethylene terephthalate) (“PET”) was patterned by conformally contacting a heterogeneous stencil of the present invention with the gold surface. A gold etchant was then applied to the openings in the stencil and allowed to react with the surface for an amount of time sufficient to etch the 70 nm-thick gold film. FIGS. 17-19 provide transmission mode optical microscopy images, 1700, 1800 and 1900, respectively, of patterned substrates resulting therefrom.

FIG. 17 provides a transmission mode optical microscopy image, 1700, that includes a substrate, 1701, having lines, 1702, etched thereon (line dimensions are approximately 20 μm×1 mm).

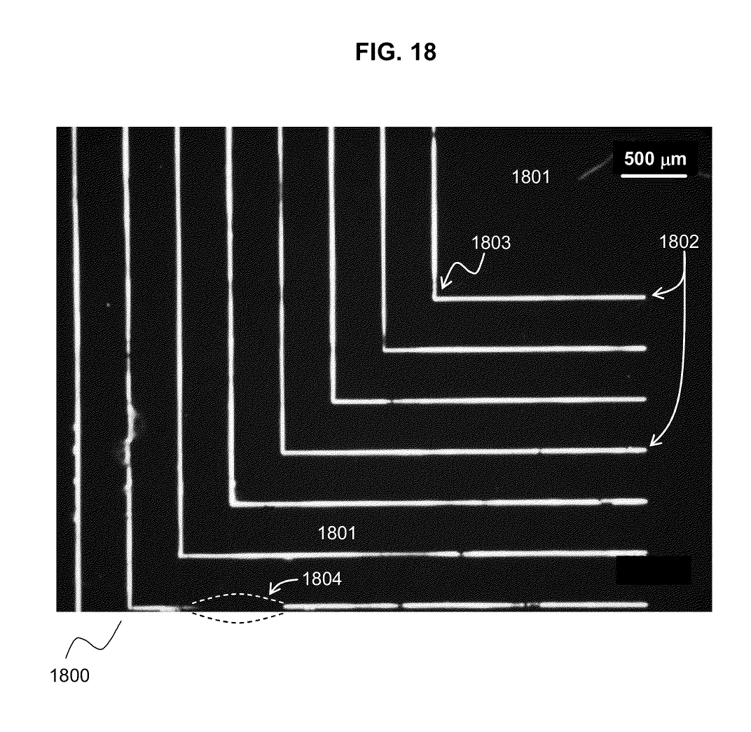

FIG. 18 provides a transmission mode optical microscopy image, 1800, which includes a substrate, 1801, having lines, 1802, that include a 90° elbow, 1803. Also shown is a defect in the pattern, 1804, arising from incomplete etching of the gold metal layer.

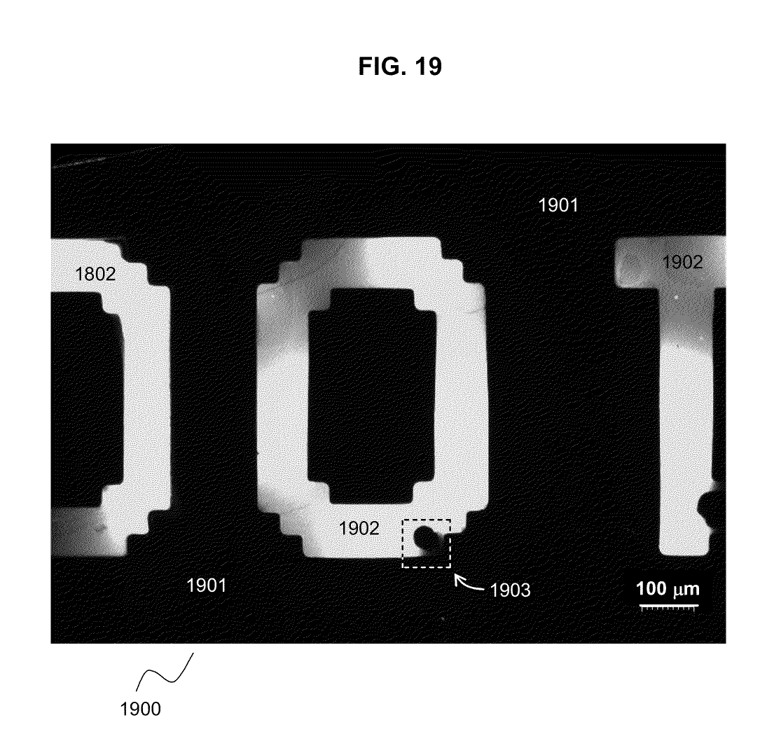

FIG. 19 provides a transmission mode optical microscopy image, 1900, that includes a substrate, 1901, having alpha-numeric characters, 1902, etched therein. Also shown is a pattern defect, 1903, arising from incomplete etching of the gold metal layer.

### Example 3

A heterogeneous stamp of the present invention was prepared as follows. A 75 mm silicon wafer was coated with photoresist (thickness of about 100 μm), which was patterned using known processes to provide a master. Poly(dimethoxysiloxane) (Dow Corning Corp., Midland, Mich.) was deposited onto the master to a thickness greater than the height of the photoresist pattern (thicknesses of about 1 mm to about 20 mm are suitable). The poly(dimethoxysiloxane) was cured at 70° C. for more than 4 hours (h), and the resulting elastomeric stamp was peeled from the master. The elastomeric stamp was exposed to an oxygen plasma to activate the stamp surface. A hydrophobic, fluorinated silane coating (e.g., tridecafluoro-1,1,2,2-tetrahydrooctyl)trichlorosilane, Gelest, Inc., Morrisville, Pa.) was applied to the stamp surface, but not in the indentations therein, by pressing the stamp against a flat surface coated with a thin layer of the hydrophobic, fluorinated silane. The indentations in the surface of the stamp were then coated with a hydrophilic silane by exposing the stamp to a silane vapor. This two-step silanization process provided an elastomeric stamp having differential surface energies at the raised and recessed portions of the stamp. An aqueous reactive substance (an etch paste) was deposited on the stamp surface. Excess reactive substance was removed using a roller-blade, resulting in preferential deposition of the etch paste in the indentations in the stamp surface. The stamp was then conformally contacted with a substrate (e.g., ITO-coated glass), thereby etching areas of the substrate in a pattern corresponding to the pattern of indentations in the elastomeric stamp.

### Example 4

A heterogeneous stamp of the present invention was prepared as follows. A 75 mm silicon wafer was coated with photoresist (thickness of about 100 μm), which was patterned using known processes to provide a master. The master was spin-coated with an aqueous poly(vinylalcohol) solution (e.g., about 1-20% by weight), wherein the resulting poly(vinylalcohol) coating had a thickness less than the height of the photoresist pattern (e.g., a poly(vinylalcohol) coating thickness of about 10 μm to about 50 μm was typically used). The coating was dried (by removing the water therefrom), to provide a hydrophilic coating layer on the master, wherein the coating layer contained openings there through corresponding to the pattern of the master. Onto the hydrophilic coating layer was applied poly(dimethoxysiloxane), wherein the thickness of the poly(dimethoxysiloxane) was greater than the height of the photoresist pattern of the master (a coating thickness of about 1 mm to about 20 mm was typically used). The poly(dimethoxysiloxane) was cured by heating at 70° C. for more than 4 h to provide a heterogeneous elastomeric stamp comprising a hydrophilic surface having hydrophobic indentations therein. The heterogeneous elastomeric stamp was peeled from the master.

A cross-sectional schematic representation of this process is depicted in FIGS. 4A-4E.

### Example 5

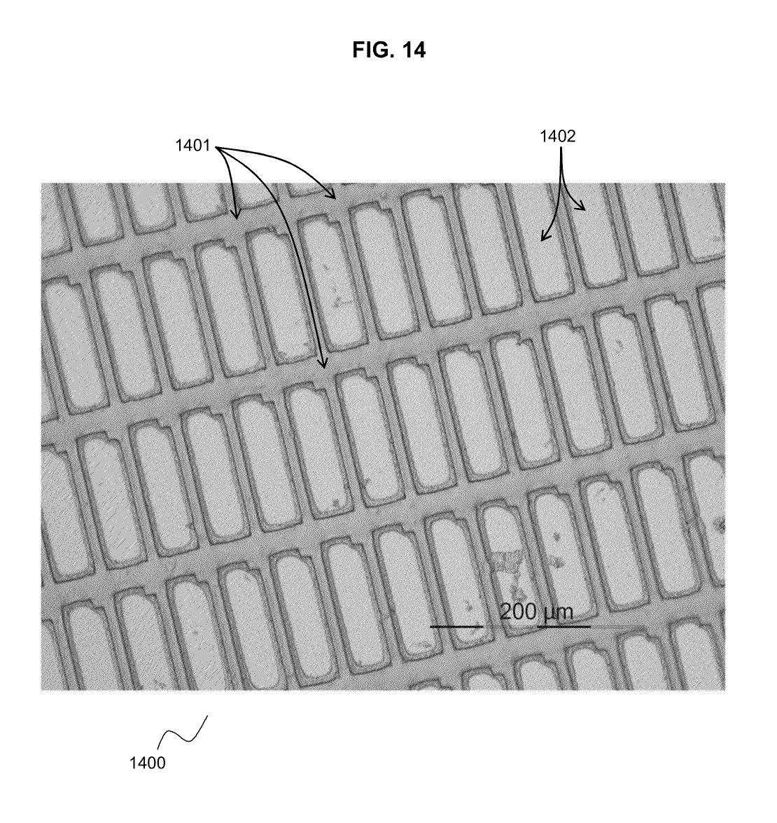

A patterned elastomeric layer suitable for use with a stencil of the present invention was prepared as follows. A photoimageable elastomeric precursor was spin-coated onto a surface (a silicon wafer, 75 cm² surface area). The photoimageable elastomeric precursor was prepared by mixing the following components: V9827 (24 g, Kuraray Co., Ltd.), SR9003 (5 g, Sartomer), Irgacure 907 (1 g, Ciba Chemicals), Esacure TZT (0.2 g, Lamberti), BHT (0.4 g, Sigma), and xylene (100 mL) until a substantially homogeneous composition was obtained. until a substantially homogeneous composition was obtained. A photomask was placed proximate to the coating layer and the layer was illuminated with 365 nm light for a time period of about 7 seconds. The photoimaged layer was developed by rinsing with toluene to generate a patterned elastomeric layer having a thickness of about 6 μm. An optical microscopy image of the patterned elastomeric layer is provided in FIG. 14. Referring to FIG. 14, the image 1400, shows regions of the silicon surface, 1402, visible through the patterned elastomeric layer, 1401.

### Hypothetical Example A

A heterogeneous stencil of the present invention could be prepared as follows. The patterned elastomeric layer provided in Example 5 could be affixed to a rigid porous membrane. The affixing could occur by pressing a porous membrane (e.g., porous glass or porous polycarbonate having a thickness of about 50 μm to about 1,000 μm) onto the patterned elastomeric layer, and then separating the porous membrane with the patterned elastomer affixed thereto, from the silicon surface to provide a stencil. A cross-sectional schematic representation of this process is depicted in FIGS. 6A-6E.

### Example 6

A patterned elastomeric layer suitable for use with a stencil of the present invention was prepared as follows. A surface (a silicon wafer, 75 cm² surface area) was spin-coated with a photoresist layer (SU-8 photoresist, MicroChem. Corp., Newton, Mass.). The resulting layer was partially soft-baked by heated starting at 65° C., and after the temperature was increased to 95° C., the soft-bake cycle was interrupted and a porous membrane (a 1 inch diameter porous glass membrane having a pore size of about 1 μm and thickness of 3 mm, Schott Glass, Elmsford, N.Y.) was pressed into the surface of the spin-coated photoresist layer. Separation of the porous membrane from the substrate resulted in transfer of the partially-baked photoresist layer to the porous membrane. The coated photoresist layer on the porous membrane was then exposed, post-exposure baked, developed, rinsed and dried using known processes to provide a heterogeneous stencil having a contact layer with a thickness of about 5 μm, and porous glass membrane backing layer.

### Example 7

A heterogeneous stencil of the present invention was prepared as follows. A nylon membrane (75 cm² surface area, Sterlitech, Wash.) having an average pore size of about 800 nm was spin-coated with a photoresist layer (SU-8 photoresist, MicroChem. Corp., Newton, Mass.). The coated photoresist was soft-baked, exposed, post-exposure baked, developed, rinsed and dried using known processes to provide a heterogeneous stencil having a contact layer with a thickness of about 5 μm, and porous nylon membrane backing layer. A cross-sectional schematic representation of this process is depicted in FIGS. 10A-10D.

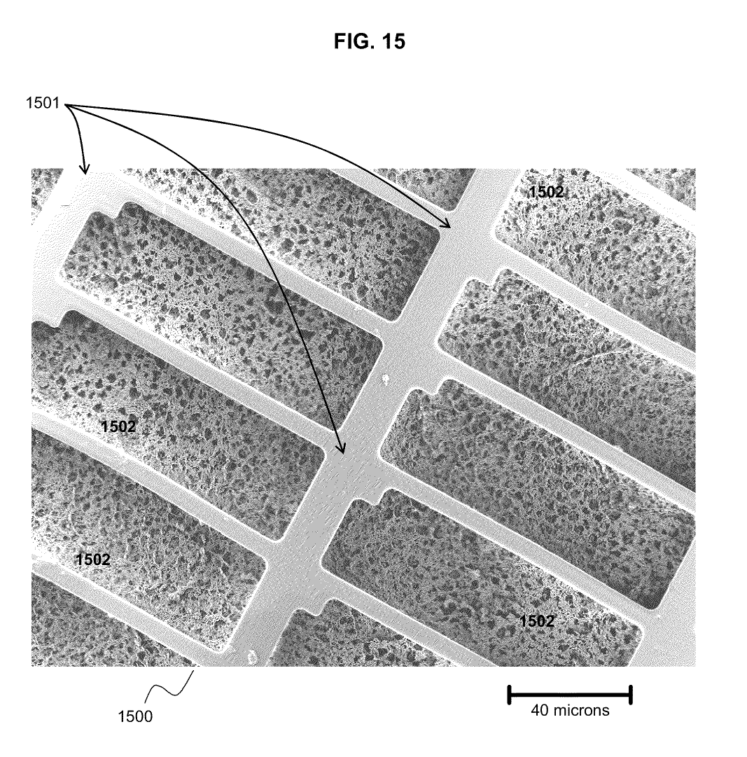

FIG. 15 provides a scanning electron microscope image, 1500, of the heterogeneous stencil. Referring to FIG. 15, the contact layer, 1501, which is a patterned layer of SU-8 photoresist is affixed to a porous membrane, 1502, having an average pore size of about 450 nm.

### Example 8

A heterogeneous stencil of the present invention was prepared as follows. A polyethersulfone membrane (75 cm² surface area) was spin-coated with a photoimageable elastomeric precursor. The photoimageable elastomeric precursor was prepared as in Example 5. After coating, photoimageable elastomeric precursor was then exposed by placing a photomask proximate to the coated layer and illuminating the coated layer with 365 nm light for a time period of about 7 seconds. The photoimaged layer was developed by rinsing with toluene to generate a heterogeneous stencil having a contact layer with a thickness of about 6 μm, and a porous polyethersulfone membrane. A cross-sectional schematic representation of this process is depicted in FIGS. 10A-10D.

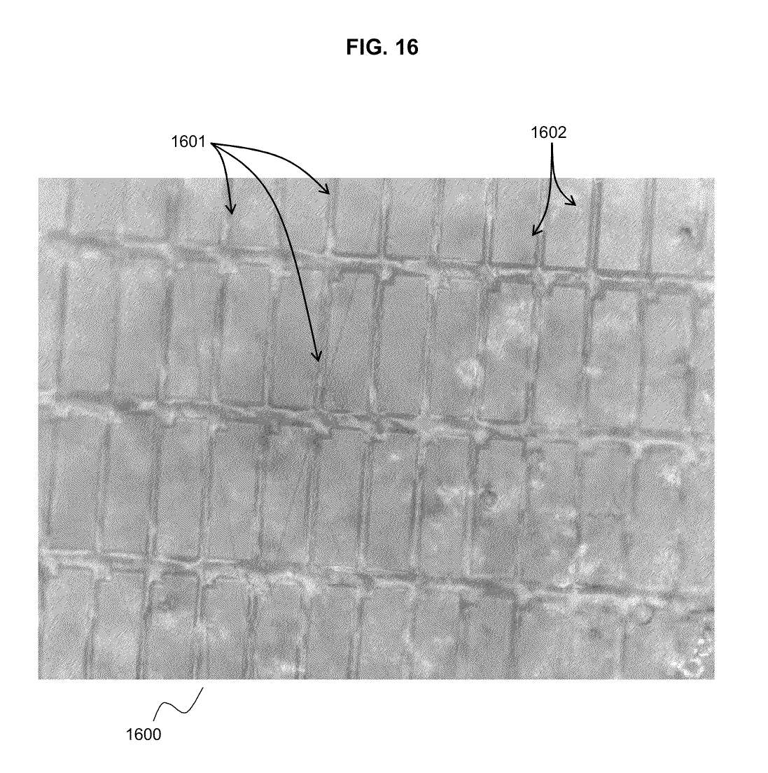

FIG. 16 provides an optical microscopy image, 1600, of the heterogeneous stencil. Referring to FIG. 16, the contact layer, 1601, which is a patterned elastomer (prepared by photoimaging) is affixed to a porous membrane, 1602, having an average pore size of about 2-4 μm.

### Example 9

A heterogeneous stencil of the present invention was prepared as in Example 8, except that a track-etch polycarbonate membrane having a surface area of 20 cm² and an average pore size of 1 μm was utilized.

### CONCLUSION

These examples illustrate possible embodiments of the present invention. While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

It is to be appreciated that the Detailed Description section, and not the Summary and Abstract sections, is intended to be used to interpret the claims. The Summary and Abstract sections can set forth one or more, but not all exemplary embodiments of the present invention as contemplated by the inventor(s), and thus, are not intended to limit the present invention and the appended claims in any way.

All documents cited herein, including journal articles or abstracts, published or corresponding U.S. or foreign patent applications, issued or foreign patents, or any other documents, are each entirely incorporated by reference herein, including all data, tables, figures, and text presented in the cited documents.

1. A method for forming a feature on a substrate, the method comprising:
(a) providing a stencil having a front surface and a back surface,
wherein the front surface of the stencil includes an elastomeric material that defines a pattern thereon, the pattern comprising a plurality of openings having at least one lateral dimension of about 100 μm or less,
wherein the back surface of the stencil includes a porous membrane that is affixed to at least a portion of the elastomeric material, and
wherein the front surface of the stencil has a flatness of about 20% or less of the stencil thickness;
(b) conformally contacting the front surface of the stencil with a substrate; and
(c) applying a reactive composition to the back surface of the stencil, wherein the reactive composition permeates the porous membrane and reacts to produce a patterned substrate having a feature thereon, wherein the feature has a lateral dimension corresponding to the plurality of openings in the front surface of the stencil.

2. The method of claim 1, further comprising: removing the stencil from the patterned substrate before the reactive composition has completed reacting.

3. A method for forming a feature on a substrate, the method comprising:
(a) providing a stencil having a front surface and a back surface,
wherein the front surface of the stencil includes an elastomeric material that defines a pattern thereon, the pattern comprising a plurality of openings having a minimum lateral dimension of about 100 μm or less,
wherein the back surface of the stencil includes a porous membrane that is affixed to at least a portion of the elastomeric material,
(b) conformally contacting the front surface of the stencil with a substrate;
(c) applying a reactive composition to the back surface of the stencil, wherein the reactive composition permeates the porous membrane and contacts the substrate;
(d) removing the stencil from the substrate; and
(e) reacting the reactive composition with the substrate to produce a patterned substrate having a feature thereon, wherein the feature has a lateral dimension corresponding to the plurality of openings in the front surface of the stencil.

4. (canceled)

5. The method of claim 1, further comprising before the conformally contacting, pre-treating or cleaning at least one of: the front surface of the stencil, the substrate, the porous membrane, or a combination thereof.

6. The method of claim 1, wherein the applying comprises applying a reactive composition with: fluid pressure, mechanical pressure, or a combination thereof.

7. The method of claim 1, wherein the applying and the reacting comprise a reactive composition that includes an etchant.

8. The method of claim 1, wherein the applying and the reacting comprise a reactive composition that includes an etchant and has a viscosity of about 100 cP to about 10,000 cP.

9. The method of claim 1, wherein the applying and the reacting comprise a reactive composition that includes a metal nanoparticle.

10. The method of claim 1, wherein the applying and the reacting comprise a reactive composition that includes a metal nanoparticle and has a viscosity of about 10 cP to about 10,000 cP.

11. The method of claim 1, wherein the providing comprises a porous membrane having a thickness of about 50 μm to about 1,000 μm and an average pore size of about 100 nm to about 2 μm, and wherein the applying and the reacting comprise a reactive composition that includes a metal nanoparticle and has a viscosity of about 10 cP to about 10,000 cP.

12. The method of claim 1, wherein providing comprises an elastomeric material having a thickness not greater than five times the minimum lateral dimension of the plurality of openings.

13. The method of claim 1, wherein the providing comprises an elastomeric material that is a photoimaged elastomer selected from: a styrene butadiene rubber, a styrene isoprene rubber, a polyurethane, a polysiloxane, a polyacrylate, a polymethacrylate, and combinations thereof.

14. (canceled)

15. (canceled)

16. The method of claim 1, wherein the providing comprises a stencil that includes a rigid porous membrane having at least one surface with a flatness of about 20% or less of the porous membrane thickness, wherein the rigid porous membrane is selected from: a glass membrane, a ceramic membrane, and a polycarbonate membrane.

17. The method of claim 1, wherein the providing comprises a porous membrane selected from: a nylon membrane, a polyethersulfone membrane, a polypropylene membrane, a poly(tetrafluoroethylene) membrane, a polycarbonate membrane, a cellulose acetate membrane, a sintered plastic membrane, a carbon fiber membrane, a glass fiber membrane, a glass membrane, and a ceramic membrane.

18. (canceled)

19. A method for forming a feature on a substrate, the method comprising:
(a) providing a stencil having a front surface and a back surface,
wherein the front surface of the stencil includes a photoimaged elastomeric material that defines a pattern thereon, the pattern comprising a plurality of openings having a minimum lateral dimension of about 1 μm to about 50 μm,
wherein the back surface of the stencil includes a rigid porous membrane affixed to at least a portion of the elastomeric material, the rigid porous membrane having at least one surface with a flatness of about 20% or less of the stencil thickness and comprises a material selected from: a porous glass membrane, a porous ceramic membrane, and a porous polycarbonate membrane;
(b) conformally contacting the front surface of the stencil with a substrate;
(c) applying a reactive composition to the back surface of the stencil, wherein the reactive composition includes an etchant and has a viscosity of about 10 cP to about 100 cP, and wherein the reactive composition permeates the porous membrane and reacts to produce a patterned substrate having a feature thereon, wherein the feature has a lateral dimension corresponding to the plurality of openings in the front surface of the stencil.

20. (canceled)

21. (canceled)

22. The method of claim 1, wherein the applying further comprises initiating a reaction of the reactive composition, wherein the initiating comprises applying thermal energy, electromagnetic radiation, acoustic waves, an oxidizing or reducing plasma, an electron beam, a stoichiometric chemical reagent, a catalytic chemical reagent, an oxidizing or reducing reactive gas, an acid, a base, an increase or decrease in pressure, an alternating or direct electrical current, agitation, sonication, friction, or a combination thereof to the reactive composition, the substrate, or a combination thereof.

23. The method of claim 1, wherein the conformally contacting is achieved by applying pressure of about 10 kPa to the stencil or the substrate.

24. A method for preparing a stencil, the method comprising:
(a) coating a surface with a photoimageable elastomeric precursor to provide a coating layer comprising a photoimageable elastomeric precursor;
(b) patterning the photoimageable elastomeric precursor to provide an elastomeric layer that includes a plurality of openings therein, the openings having at least one lateral dimension of about 100 μm or less;
(c) affixing a porous membrane to the elastomeric layer;
(d) separating the elastomeric layer from the surface, thereby providing the stencil, wherein the front surface of the stencil has a flatness of about 20% or less of the stencil thickness.

25. A method for preparing a stencil, the method comprising:
(a) coating a porous membrane with a photoimageable elastomeric precursor to provide a coating layer comprising a photoimageable elastomeric precursor; and
(b) patterning the photoimageable elastomeric precursor coating layer to provide the stencil comprising a patterned elastomeric layer on the porous membrane, wherein the patterned elastomeric layer includes a plurality of openings therein, the openings having at least one lateral dimension of about 100 μm or less, and wherein the front surface of the stencil has a flatness of about 20% or less of the stencil thickness.

26. The method of claim 24, wherein the coating comprises providing a photoimageable elastomeric precursor having a thickness of about 1 μm to about 30 μm.

27. The method of claim 24, wherein the patterning comprises:
(i) positioning a photomask proximate to the coating layer comprising a photoimageable elastomeric precursor;
(ii) exposing the photoimageable precursor through the photomask with UV radiation for about 0.1 seconds to about 100 seconds to provide a photoimaged coating layer;
(iii) developing the photoimaged coating layer to remove regions of the photoimaged coating layer and provide a patterned elastomeric layer; and
(iv) drying the surface of the patterned elastomeric layer.

28. (canceled)

29. The method of claim 24, wherein the patterning provides an elastomeric layer having a thickness not greater than five times the minimum lateral dimension of the plurality of openings therein.

30. The method of claim 24, wherein the coating comprises a photoimageable elastomeric precursor that includes: a photocurable monomer, an elastomeric binder, and a photoinitiator.

31. The method of claim 30, wherein the coating comprises a photocurable monomer selected from: a linear acrylate, a branched acrylate, a methacrylate, and combinations thereof.

32. The method of claim 30, wherein the coating comprises an elastomeric binder having an accessible vinyl side-chain.

33. The method of claim 30, wherein the coating comprises an elastomeric binder is selected from: a styrene butadiene rubber, a styrene isoprene rubber, a polyurethane, and a polysiloxane.

34. The method of claim 30, wherein the coating comprises a photoinitiator selected from: Irgacure 907, Esacure TZT, Esacure SM308, and combinations thereof.

35. (canceled)

36. The method of claim 30, wherein the coating comprises a photoimageable elastomeric precursor that includes a solvent selected from: toluene, xylene, propylene glycol methyl ether acetate, and combinations thereof.

37. The method of claim 30, wherein the coating comprises a photoimageable elastomeric precursor that includes an additive selected from: a wetting agent, a stabilizer, an anti-oxidant, a photocuring accelerator, and combinations thereof.

38. The method of claim 37, wherein the coating comprises a photoimageable elastomeric precursor that includes a stabilizer selected from: 2,6-di-tert-butyl-4-methylphenol, 1,4,4-trimethyl-2,3-diazobicyclo(3.2.2)-non-2-ene-2,3-dioxide, and combinations thereof.

39. (canceled)

40. (canceled)

41. (canceled)

42. The method of claim 24, wherein the porous membrane selected from: a nylon membrane, a polyethersulfone membrane, a polypropylene membrane, a poly(tetrafluoroethylene) membrane, a polycarbonate membrane, a cellulose acetate membrane, a sintered plastic membrane, a carbon fiber membrane, a glass fiber membrane, a glass membrane, and a ceramic membrane.

43. The method of claim 24, further comprising adhering at least a portion of the porous membrane to a rigid member to provide a stencil having a front surface with a flatness of about 20% or less of the stencil thickness.

44. A product prepared by the process of claim 24.

45. (canceled)

46. A method for forming a feature on a substrate, the method comprising:
(a) providing a stencil having a front surface and a back surface,
wherein the front surface of the stencil includes a patterned elastomeric material having a thickness of about 1 μm to about 30 μm,
wherein the back surface of the stencil includes a porous membrane that is affixed to at least a portion of the elastomeric material,
wherein the front surface of the stencil has a flatness of 20% or less than the stencil thickness, and
wherein the providing comprises:
coating the porous membrane with a photoimageable elastomeric precursor to provide a coating layer comprising a photoimageable elastomeric precursor;
positioning a photomask proximate to the coating layer comprising a photoimageable elastomeric precursor;
exposing the photoimageable precursor through the photomask with UV radiation for about 0.1 seconds to about 100 seconds to provide a photoimaged coating layer;
developing the photoimaged coating layer to remove regions of the photoimaged coating layer and provide a patterned elastomeric layer; and
drying the surface of the patterned elastomeric layer to provide the stencil comprising a patterned elastomeric layer on the porous membrane, wherein the patterned elastomeric layer includes a plurality of openings therein, the openings having at least one lateral dimension of about 100 μm or less;
(b) conformally contacting the front surface of the stencil with a substrate; and
(c) applying a reactive composition to the back surface of the stencil, wherein the reactive composition permeates the porous membrane and reacts to produce a patterned substrate having a feature thereon, wherein the feature has a lateral dimension corresponding to the plurality of openings in the front surface of the stencil.

47. A method for forming a feature on a substrate, the method comprising:
(a) providing a stencil having a front surface and a back surface,
wherein the front surface of the stencil includes a patterned elastomeric material having a thickness of about 1 μm to about 30 μm,
wherein the back surface of the stencil includes a porous membrane that is affixed to at least a portion of the elastomeric material,
wherein the front surface of the stencil has a flatness of 20% or less than the stencil thickness, and
wherein the providing comprises:
coating the porous membrane with a photoimageable elastomeric precursor to provide a coating layer comprising a photoimageable elastomeric precursor;
positioning a photomask proximate to the coating layer comprising a photoimageable elastomeric precursor;
exposing the photoimageable precursor through the photomask with UV radiation for about 0.1 seconds to about 100 seconds to provide a photoimaged coating layer;
developing the photoimaged coating layer to remove regions of the photoimaged coating layer and provide a patterned elastomeric layer; and
drying the surface of the patterned elastomeric layer to provide the stencil comprising a patterned elastomeric layer on the porous membrane, wherein the patterned elastomeric layer includes a plurality of openings therein, the openings having at least one lateral dimension of about 100 μm or less;
(b) conformally contacting the front surface of the stencil with a substrate; and
(c) applying a reactive composition comprising a nanoparticle to the back surface of the stencil, wherein the reactive composition permeates the porous membrane and produces a patterned substrate having a feature thereon, wherein the feature has a lateral dimension corresponding to the plurality of openings in the front surface of the stencil.

48. A method for forming a feature on a substrate, the method comprising:
(a) providing a stencil having a front surface and a back surface,
wherein the front surface of the stencil includes a patterned elastomeric material having a thickness of about 1 μm to about 30 μm,
wherein the back surface of the stencil includes a porous membrane that is affixed to at least a portion of the elastomeric material,
wherein the front surface of the stencil has a flatness of 20% or less than the stencil thickness, and
wherein the providing comprises:
coating the porous membrane with a photoimageable elastomeric precursor to provide a coating layer comprising a photoimageable elastomeric precursor;
positioning a photomask proximate to the coating layer comprising a photoimageable elastomeric precursor;
exposing the photoimageable precursor through the photomask with UV radiation for about 0.1 seconds to about 100 seconds to provide a photoimaged coating layer;
developing the photoimaged coating layer to remove regions of the photoimaged coating layer and provide a patterned elastomeric layer; and
drying the surface of the patterned elastomeric layer to provide the stencil comprising a patterned elastomeric layer on the porous membrane, wherein the patterned elastomeric layer includes a plurality of openings therein, the openings having at least one lateral dimension of about 100 μm or less;
(b) conformally contacting the front surface of the stencil with a substrate; and
(c) applying a reactive composition comprising a nanoparticle to the back surface of the stencil, wherein the reactive composition permeates the porous membrane and contacts the substrate to form a patterned substrate, wherein the pattern corresponds to the plurality of openings in the front surface of the stencil;
(d) removing the stencil from the substrate; and
(e) sintering the patterned substrate at a temperature of about 60° C. to about 600° C.
